(19) United States
(12) Patent Application Publication
(10) Pub. No.: US 2026/0068491 A1
(43) Pub. Date: Mar. 5, 2026

(54) DISPLAY DEVICE, ELECTRONIC DEVICE, AND METHOD FOR MANUFACTURING DISPLAY DEVICE

(71) Applicant: Samsung Display Co., Ltd., Yongin-si (KR)

(72) Inventors: Jeong Seop CHOI, Yongin-si (KR); Dong Hyeon LEE, Yongin-si (KR); Dong Hun KANG, Yongin-si (KR); Yong Woo KIM, Yongin-si (KR); Jeong In LEE, Yongin-si (KR)

(21) Appl. No.: 19/177,270

(22) Filed: Apr. 11, 2025

(30) Foreign Application Priority Data
Sep. 4, 2024 (KR) 10-2024-0119872

(51) Int. Cl. H10K 59/80; H10K 59/12

(52) U.S. Cl. CPC H10K 59/873; H10K 59/1201

(57) ABSTRACT

A display device and a method for manufacturing the display device are provided. The display device includes, a display panel, an upper member disposed on the display panel, and an adhesive member between the display panel and the upper member. The adhesive member includes a first portion containing a first resin, a second portion containing a second resin having a higher modulus than the first resin and on at least one side of the first portion, and a third portion containing the first resin and the second resin and between the first portion and the second portion, wherein each of the first resin and the second resin contained in the third portion is in direct contact with a bottom surface of the upper member.

### CROSS-REFERENCE TO RELATED APPLICATION

The present application claims priority to and the benefit of Korean Patent Application No. 10-2024-0119872, filed on Sep. 4, 2024, in the Korean Intellectual Property Office, the entire content of which is incorporated herein by reference.

### BACKGROUND

### 1. Field

One or more embodiments of the present disclosure relate to a display device, an electronic device, and a method for manufacturing the display device.

### 2. Description of the Related Art

With the advancement of information-oriented society, increasing demands are placed on display devices for displaying images in one or more suitable ways. The display device may be a liquid crystal display, a field emission display, or a light emitting display. The light emitting display may include an organic light emitting display device with an organic light emitting diode as a light emitting element or an inorganic light emitting display device with an inorganic light emitting diode as a light emitting element.

Recently, bendable display devices, where the display area can be bent, and foldable display devices, where the display area can be folded, have been developed and released to provide a wide display screen while simultaneously increasing the portability of the display devices.

The display device may include a display panel including a light emitting element, and one or more suitable members may be arranged above (e.g., on top of) the display panel to protect the display panel from external impact. Such an upper member may be arranged on the display panel via an adhesive member.

### SUMMARY

One or more aspects of embodiments of the present disclosure are directed toward a display device with enhanced (e.g., improved) foldability, an electronic device including the display device, and a method for manufacturing the display device.

One or more aspects of embodiments of the present disclosure are directed toward a display device including an adhesive member with enhanced (e.g., improved) thickness uniformity and a method for manufacturing the display device.

However, aspects of the present disclosure are not restricted to those set forth herein. The above and other aspects of the present disclosure will become more apparent to one of ordinary skill in the art to which the present disclosure pertains by referencing the detailed description of the present disclosure provided herein or learning by practice of the presented embodiments of the disclosure.

According to one or more embodiments of the present disclosure, a display device includes: a display panel; an upper member on (e.g., arranged on) the display panel; and an adhesive member between (e.g., arranged between) the display panel and the upper member, wherein the adhesive member includes a first portion containing a first resin, a second portion containing a second resin having a higher modulus than the first resin and on (e.g., arranged on) at least one side of the first portion, and a third portion containing the first resin and the second resin and between (e.g., arranged between) the first portion and the second portion, wherein each of the first resin and the second resin contained in the third portion is in direct contact with a bottom surface of the upper member.

In one or more embodiments, each of the first resin and the second resin contained in the third portion may be (e.g., is) in direct contact with a top surface of the display panel.

In one or more embodiments, an amount of the first resin contained in the third portion may be (e.g., is) equal to an amount of the second resin contained in the third portion.

In one or more embodiments, a density of the third portion may be (e.g., is) greater than a density of the first portion and less than a density of the second portion, or the density of the third portion may be (e.g., is) less than the density of the first portion and greater than the density of the second portion.

In one or more embodiments, the density of the third portion may be (e.g., is) about 0.9 to about 1.1 times an average value of the density of the first portion and the density of the second portion.

In one or more embodiments, the density of the third portion may be (e.g., is) equal to the average value of the density of the first portion and the density of the second portion.

In one or more embodiments, a difference between a maximum density and a minimum density of the third portion may be (e.g., is) within about 0.2 times an average value of densities of the third portion.

In one or more embodiments, a thickness deviation of the third portion may be (e.g., is) within about 5 micrometers (μm).

In one or more embodiments, in the third portion, the first resin and the second resin do not overlap each other in a thickness direction of the adhesive member.

In one or more embodiments, in the third portion, a boundary between a side surface of the first resin and a side surface of the second resin may be (e.g., is) an inclined surface.

In one or more embodiments, the display panel includes a folding area and a non-folding area arranged on a (e.g., one) side of the folding area, and the first portion overlaps the folding area, the second portion overlaps the non-folding area, and the third portion is adjacent to a boundary between the folding area and the non-folding area.

In one or more embodiments, a modulus of the second portion may be (e.g., is) greater than a modulus of the first portion.

In one or more embodiments, a modulus of the third portion may be (e.g., is) greater than the modulus of the first portion and less than the modulus of the second portion.

In one or more embodiments, the first portion and the second portion are not in direct contact with each other.

According to one or more embodiments of the present disclosure, there is provided a method for manufacturing a display device, the method including: generating a first application pattern and a second application pattern; ejecting first ink according to the first application pattern; ejecting second ink according to the second application pattern, and curing the first ink and the second ink, wherein the second application pattern is an inverse pattern of the first application pattern.

In one or more embodiments, each of the first application pattern and the second application pattern may be (e.g., is) a bitmap, a portion of the first application pattern at which a bit is indicated coincides with a portion of the second application pattern at which a bit is not indicated, and a portion of the first application pattern at which a bit is not indicated coincides with a portion of the second application pattern at which a bit is indicated.

In one or more embodiments, in the first application pattern, a proportion of the portion at which the bit of the first application pattern is indicated and a proportion of the portion at which the bit of the first application pattern is not indicated may be (e.g., are) substantially equal to each other.

In one or more embodiments, a point where the first ink is ejected and a point where the second ink is ejected do not overlap.

In one or more embodiments, the first application pattern may be (e.g., is) a random pattern.

In one or more embodiments, each of the first ink and the second ink contains an optical clear resin, and a modulus of the first ink is less than a modulus of the second ink.

According to the display device and the method for manufacturing the display device of one or more embodiments of the present disclosure, the foldability of the display device may be enhanced (e.g., improved.)

According to the display device and the method for manufacturing the display device according to one or more embodiments of the present disclosure, the thickness uniformity of the display device may be enhanced (e.g., improved).

For example, according to the display device and the method for manufacturing the display device of one or more embodiments of the present disclosure, the foldability and thickness uniformity of the display device may be enhanced (e.g., improved). This is achieved through the incorporation of an adhesive member with a multi-sectioned structure, where each section is composed of resins with varying moduli. The first portion of the adhesive member, which overlaps the folding area of the display panel, contains a first resin with a lower modulus, providing flexibility and durability during repeated folding. The second portion, overlapping the non-folding area, contains a second resin with a higher modulus, ensuring structural integrity and support. The third portion, positioned between the first and second portions, contains a mixture of the first and second resins, offering a gradual transition in mechanical properties. This configuration reduces or minimizes stress concentration and potential damage at the boundary between the folding and non-folding areas, thereby enhancing foldability. Additionally, the method involves generating precise application patterns for the first and second inks, which are then ejected and cured to form the adhesive member. By ensuring that the application patterns do not overlap and that the proportions of indicated and non-indicated bits are substantially equal, the method achieves a uniform distribution of the resins. This results in an adhesive member with consistent thickness and density, reducing variations that could affect the display device's performance and contributing to its reliability and longevity.

It should be noted that effects and aspects of the present disclosure are not limited to those described above and other effects and aspects of the present disclosure will be apparent to those skilled in the art from the following descriptions.

### BRIEF DESCRIPTION OF THE DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects and features of the present disclosure will become more apparent and appreciated from the following descriptions of example embodiments thereof with reference to the accompanying drawings, in which:

FIG. 1 is a perspective view illustrating a display device in an unfolded state according to one or more embodiments of the present disclosure;

FIG. 2 is a perspective view illustrating a display device in a folded state according to one or more embodiments of the present disclosure;

FIG. 3 is a perspective view illustrating a display device in an unfolded state according to one or more embodiments of the present disclosure;

FIG. 4 is a perspective view illustrating a display device in a folded state according to one or more embodiments of the present disclosure;

FIG. 5 is an exploded perspective view showing a display device according to one or more embodiments of the present disclosure;

FIG. 6 is a cross-sectional view taken along the line X1-X1′ of FIG. 5 according to one or more embodiments of the present disclosure;

FIG. 7 is a cross-sectional view illustrating an example of a display panel according to one or more embodiments of the present disclosure;

FIG. 8 is a plan view showing an example of an adhesive member according to one or more embodiments of the present disclosure;

FIG. 9 is a plan view showing another example of an adhesive member according to one or more embodiments of the present disclosure;

FIG. 10 is a plan view showing still another example of an adhesive member according to one or more embodiments of the present disclosure;

FIG. 11 is a cross-sectional view showing an example of a cross-section of a display device taken along the line X2-X2′ of FIG. 10 according to one or more embodiments of the present disclosure;

FIG. 12 is a cross-sectional view showing an example of a cross-section of a display device taken along the line X2-X2′ of FIG. 10 according to one or more embodiments of the present disclosure;

FIG. 13 is a cross-sectional view showing a folded state of the display device of FIG. 11 according to one or more embodiments of the present disclosure;

FIG. 14 is an enlarged schematic diagram illustrating area A of FIG. 10 according to one or more embodiments of the present disclosure;

FIG. 15 is an enlarged plan view illustrating area A of FIG. 10 according to one or more embodiments of the present disclosure;

FIG. 16 is a schematic diagram illustrating an enlarged cross-section of area B of FIG. 11 according to one or more embodiments of the present disclosure;

FIG. 17 is a cross-sectional view illustrating an example of an enlarged cross-section of area B of FIG. 11 according to one or more embodiments of the present disclosure;

FIG. 18 is a cross-sectional view illustrating another example of an enlarged cross-section of area B of FIG. 11 according to one or more embodiments of the present disclosure;

FIG. 19 is a flowchart showing a method for manufacturing a display device according to one or more embodiments of the present disclosure;

FIG. 20 is a bitmap image illustrating a first application pattern of the step S100 of FIG. 19 according to one or more embodiments of the present disclosure;

FIG. 21 is a schematic diagram illustrating a first application pattern of the step S100 of FIG. 19 according to one or more embodiments of the present disclosure;

FIG. 22 is a bitmap image illustrating a second application pattern of the step S200 of FIG. 19 according to one or more embodiments of the present disclosure;

FIG. 23 is a schematic diagram illustrating a second application pattern of the step S200 of FIG. 19 according to one or more embodiments of the present disclosure;

FIG. 24 is a bitmap image illustrating a reference pattern in which the first application pattern and the second application pattern are combined according to one or more embodiments of the present disclosure;

FIG. 25 is a schematic diagram illustrating a reference pattern in which the first application pattern and the second application pattern are combined according to one or more embodiments of the present disclosure;

FIG. 26 is a cross-sectional view showing the step S300 of FIG. 19 according to one or more embodiments of the present disclosure;

FIG. 27 is an enlarged cross-sectional view of area C of FIG. 26 according to one or more embodiments of the present disclosure;

FIG. 28 is a cross-sectional view showing the step S400 of FIG. 19 according to one or more embodiments of the present disclosure;

FIG. 29 is a cross-sectional view of area D of FIG. 28 according to one or more embodiments of the present disclosure;

FIGS. 30 and 31 are each a cross-sectional view showing the step S500 of FIG. 19 according to one or more embodiments of the present disclosure;

FIG. 32 is a cross-sectional view showing a part of a display device according to a first comparative example of the present disclosure;

FIG. 33 is a cross-sectional view showing a part of a display device according to a second comparative example of the present disclosure; and

FIG. 34 is a graph illustrating the thickness profiles of the adhesive members of the display devices according to a first comparative example, a second comparative example, and one embodiment of the present disclosure.

### DETAILED DESCRIPTION

The present disclosure will now be described more fully hereinafter with reference to the accompanying drawings, in which example embodiments of present disclosure are shown. This disclosure may, however, be embodied in different forms and should not be construed as limited to one or more embodiments set forth herein. Rather, these embodiments are provided so that this disclosure will be thorough and complete, and will fully convey the scope of present disclosure to those skilled in the art.

It will also be understood that if (e.g., when) a layer is referred to as being “on” another layer or substrate, it may be directly on the other layer or substrate, or one or more intervening layers may also be present therebetween. In contrast, “directly on” may refer to that there are no additional intervening elements or layers between the element or layer and the another element or layer. The same or like reference numbers indicate the same or like components throughout the disclosure, and duplicative descriptions thereof may not be provided for conciseness.

Hereinafter, one or more embodiments of the present disclosure will be described in more detail with reference to the accompanying drawings. Various embodiments may be practiced individually or in combination.

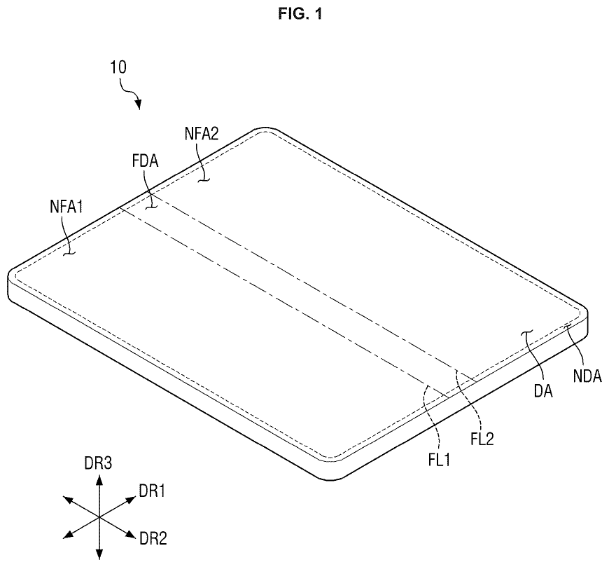

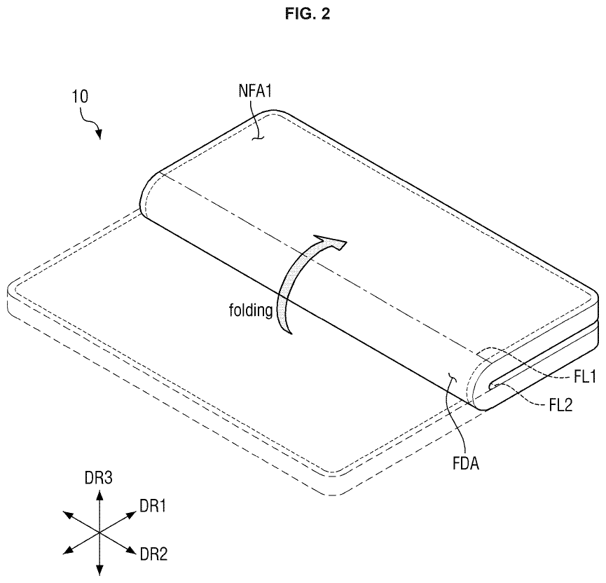

FIG. 1 is a perspective view illustrating a display device in an unfolded state according to one or more embodiments of the present disclosure. FIG. 2 is a perspective view illustrating a display device in a folded state according to one or more embodiments.

Referring to FIG. 1 and FIG. 2, FIG. 1 illustrates a first state of a display device 10, which is unfolded without being folded at folding lines FL1 and FL2, and FIG. 2 illustrates a second state of the display device 10, which is folded at folding lines FL1 and FL2.

The display device 10 according to one or more embodiments, which is a device for displaying a moving image or a still image, may be used as a display screen of one or more suitable electronic devices (e.g., electronic products), such as televisions, laptop computers, monitors, billboards, and the Internet of Things (IOT) as well as portable electronic devices such as mobile phones, smart phones, tablet personal computers (tablet PCs), smart watches, watch phones, mobile communication terminals, electronic notebooks, electronic books, portable multimedia players (PMPs), navigation systems, and/or ultra mobile PCs (UMPCs).

A planar shape of the display device 10 may have a quadrilateral shape such as a rectangle. Each of the corners of the display device 10 may be right-angled or rounded in a plan view. In one or more embodiments, a front surface of the display device 10 may include two short sides arranged in a first direction DR1 and two long sides arranged in a second direction DR2.

In the illustrated drawing, the first direction DR1 and the second direction DR2 cross each other as horizontal directions. For example, the first direction DR1 and the second direction DR2 may be orthogonal to each other. In addition, a third direction DR3 crosses the first direction DR1 and the second direction DR2, and may be, for example, a direction orthogonal to each of the first direction DR1 and the second direction DR2. Unless otherwise defined, in the present disclosure, directions indicated by arrows of the first to third directions DR1, DR2, and DR3 may be referred to as one side, and the opposite directions thereto may be referred to as the other side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display device 10 may include a display area DA and a non-display area NDA. A planar shape of the display area DA may conform to the planar shape of the display device 10. For example, if (e.g., when) the planar shape of the display device is rectangular, the planar shape of the display area DA may also be rectangular.

The display area DA may be an area including a plurality of pixels to display an image. The non-display area NDA may be an area that does not include pixels and does not display an image. The non-display area NDA may be arranged around the display area DA. In one or more embodiments, the non-display area NDA may be arranged to be around (e.g., surround) the display area DA, but embodiments of the present disclosure are not limited thereto. In one or more embodiments, the display area DA may be partially surrounded by the non-display area NDA.

The display device 10 may maintain a first state, which is an unfolded state, or a second state, which is a folded state. In one or more embodiments, the display device 10 may be folded in an in-folding manner such that the display areas DA face each other, as illustrated in FIG. 2. In these embodiments, the front surfaces of the display device 10 may face each other during the folding. In one or more embodiments, the display device 10 may be folded in an out-folding manner such that rear surfaces thereof face each other.

The display device 10 may include a folding area FDA, a first non-folding area NFA1, and a second non-folding area NFA2. The folding area FDA may be an area in which the display device 10 is folded or bent, and the first non-folding area NFA1 and the second non-folding area NFA2 may each be an area in which the display device 10 is not folded or bent. In one or more embodiments, the first non-folding area NFA1 and the second non-folding area NFA2 may each be a flat area of the display device 10.

The first non-folding area NFA1 may be arranged on one side, for example, the left side of the folding area FDA. The second non-folding area NFA2 may be arranged on the other side, for example, the right side of the folding area FDA. The folding area FDA is an area defined by the first folding line FL1 and the second folding line FL2, and may be an area in which the display device 10 is bent at a set or predetermined curvature. The first folding line FL1 may be a boundary between the folding area FDA and the first non-folding area NFA1, and the second folding line FL2 may be a boundary between the folding area FDA and the second non-folding area NFA2.

In one or more embodiments, the first folding line FL1 and the second folding line FL2 may each extend in the second direction DR2 as illustrated in FIGS. 1 and 2, and in these embodiments, the display device 10 may be folded with respect to the second direction DR2. Accordingly, the length of the display device 10 in the first direction DR1 may be reduced to approximately (e.g., about or substantially) half when the display device 10 is folded, so that a user can conveniently carry the display device 10.

The first non-folding area NFA1 may be arranged on one side, for example, the left side of the folding area FDA. The second non-folding area NFA2 may be arranged on the other side, for example, the right side of the folding area FDA. Here, the left side may refer to one side of the first direction DR1, and the right side may refer to the other side of the first direction DR1.

When the first folding line FL1 and the second folding line FL2 extend in the second direction DR2 as shown in FIGS. 1 and 2, a length of the folding area FDA in the second direction DR2 may be greater than a length of the folding area FDA in the first direction DR1. Further, a length of the first non-folding area NFA1 in the second direction DR2 may be greater than a length of the first non-folding area NFA1 in the first direction DR1. A length of the second non-folding area NFA2 in the second direction DR2 may be greater than a length of the second non-folding area NFA2 in the first direction DR1.

Each of the display area DA and the non-display area NDA may overlap at least one of the folding area FDA, the first non-folding area NFA1, or the second non-folding area NFA2. FIG. 1 and FIG. 2 illustrate that each of the display area DA and the non-display area NDA overlaps the folding area FDA, the first non-folding area NFA1, and the second non-folding area NFA2.

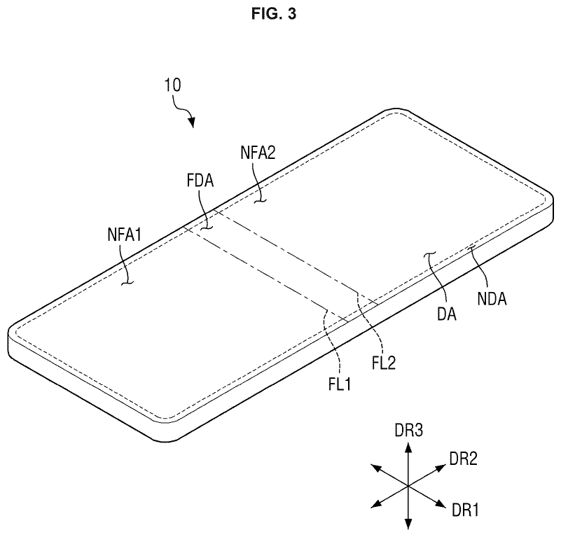

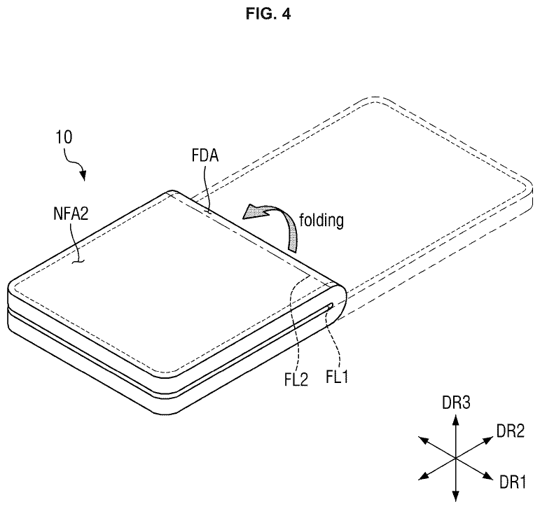

FIG. 3 is a perspective view illustrating a display device in an unfolded state according to one or more embodiments of the present disclosure. FIG. 4 is a perspective view illustrating a display device in a folded state according to one or more embodiments of the present disclosure.

Referring to FIG. 3 and FIG. 4, FIG. 3 illustrates a first state of a display device 10, which is unfolded without being folded at folding lines FL1 and FL2, and FIG. 4 illustrates a second state of the display device 10, which is folded at the folding lines FL1 and FL2.

The embodiments of FIGS. 3 and 4 are different from the embodiments of FIGS. 1 and 2 only in that a first folding line FL1 and a second folding line FL2 each extend in the first direction DR1, and the display device 10 may be folded in the second direction DR2, and thus the length of the display device 10 in the second direction DR2 is reduced by approximately half when the display device 10 is folded. Therefore, in FIGS. 3 and 4, descriptions of the parts already described in the embodiments of FIGS. and 2 will not be provided for conciseness.

In the first state in which the display device 10 is unfolded, the long side of the display device 10 may extend along the second direction DR2, and the short side of the display device 10 may extend along the first direction DR1.

The first folding line FL1 and the second folding line FL2 may each extend in the first direction DR1 as illustrated in FIG. 3 and FIG. 4, and in this regard, the display device 10 may be folded with respect to the first direction DR1.

A first non-folding area NFA1 may be arranged on one side, for example, a lower side, of a folding area FDA. A second non-folding area NFA2 may be arranged on the other side, for example, an upper side, of the folding area FDA. Here, the upper side may refer to one side of the second direction DR2, and the lower side may refer to the other side of the second direction DR2.

When the first folding line FL1 and the second folding line FL2 each extend in the first direction DR1 as illustrated in FIG. 3 and FIG. 4, a length of the folding area FDA in the first direction DR1 may be greater than a length in the second direction DR2. Further, a length of the first non-folding area NFA1 in the second direction DR2 may be greater than a length of the first non-folding area NFA1 in the first direction DR1. A length of the second non-folding area NFA2 in the second direction DR2 may be greater than a length of the second non-folding area NFA2 in the first direction DR1.

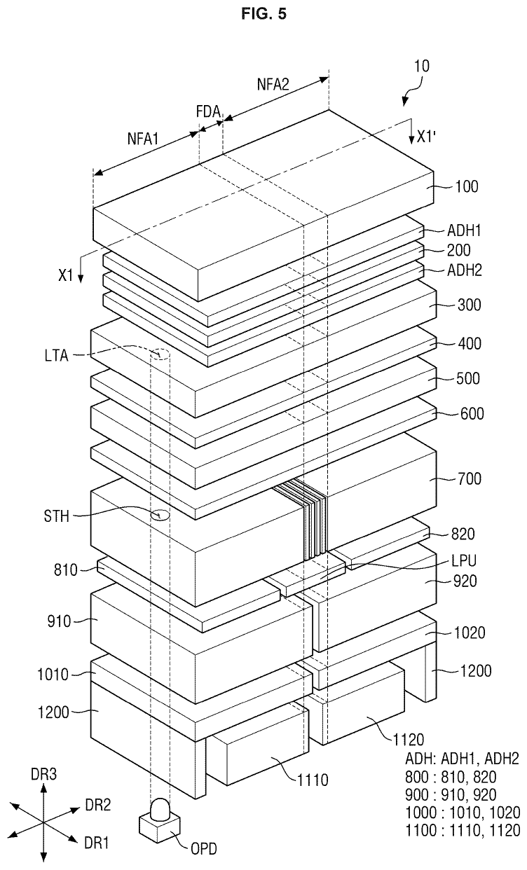

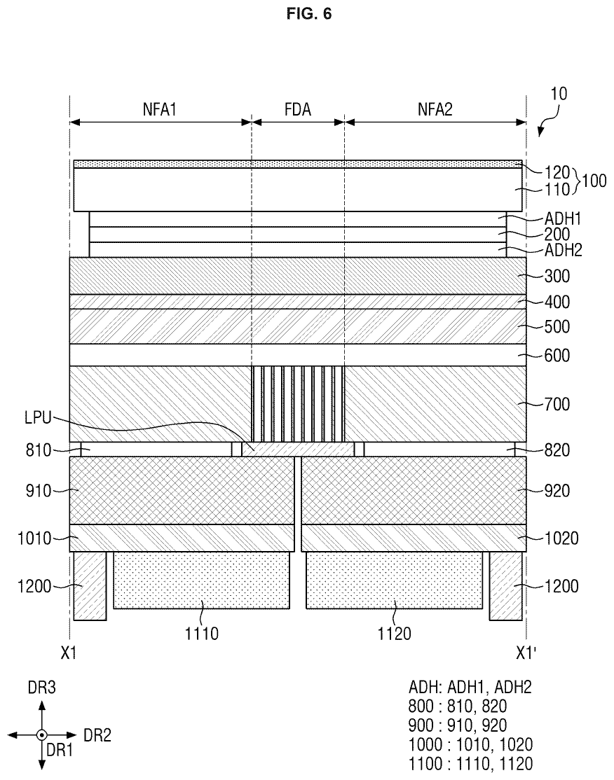

FIG. 5 is an exploded perspective view showing a display device according to one or more embodiments of the present disclosure. FIG. 6 is a cross-sectional view taken along the line X1-X1′ of FIG. 5 according to one or more embodiments of the present disclosure.

Referring to FIG. 5 and FIG. 6, a display device 10 according to one or more embodiments may include an upper protective member 100, a first adhesive member ADH1, a window member 200, a second adhesive member ADH2, an optical member 300, a display panel 400, a panel protection member 500, a panel lower member 600, a panel support member 700, a third adhesive member 800, a lower visibility prevention member LPU, a digitizer member 900, a metal support member 1000, a buffer member 1100, and a fourth adhesive member 1200.

The display panel 400 may be a panel that displays an image. The display panel 400 may be an organic light emitting display panel including an organic light emitting layer, a quantum dot light emitting display panel including a quantum dot light emitting layer, an inorganic light emitting display panel using an inorganic semiconductor element as a light emitting element, or a micro light emitting display panel using a micro light emitting diode as a light emitting element. In the following description, it is exampled that the display panel 400 is an organic light emitting display panel, but embodiments of the present disclosure are not limited thereto.

In one or more embodiments, the display panel 400 may include a light transmission area LTA that overlaps an optical device OPD in the third direction DR3. The optical device OPD may be an optical sensor that detects light, and for example, may be a camera sensor, a proximity sensor, or an illuminance sensor. The light transmission area LTA may be a portion of the display area DA (FIG. 3).

In one or more embodiments, the light transmission area LTA may include a transmission area capable of transmitting light. In one or more embodiments, the light transmission area LTA may be a through hole penetrating the display panel. The light transmittance of the light transmission area LTA may be higher than the light transmittance of the display area DA excluding the light transmission area LTA. Additionally, due to the transmission area of the light transmission area LTA, the density or integration density of pixels in the light transmission area LTA may be lower than the density or integration density of pixels in the display area DA excluding the light transmission area LTA. For example, in one or more embodiments, the number of pixels per unit area in the light transmission area LTA may be less than the number of pixels per unit area in the display area DA excluding the light transmission area LTA. In one or more embodiments, the pixels per inch (PPI) in the light transmission area LTA may be less than the PPI in the display area DA excluding the light transmission area LTA.

The optical member 300 may be arranged on a front surface of the display panel 400. The optical member 300 may serve to reduce the reflection of external light. In one or more embodiments, the optical member 300 may be provided in the form of a polarizing film. In these embodiments, the optical member 300 polarizes the light passing therethrough. However, embodiments of the present disclosure are not limited thereto. In one or more embodiments, the optical member 300 may be mounted in the display panel 400 and provided as a color filter layer.

The window member 200 may be arranged on a front surface of the optical member 300. The window member 200 may be made of a transparent material, and for example, may be glass or plastic. For example, in one or more embodiments, the window member 200 may be an ultra thin glass (UTG) having a thickness of 0.1 mm or less or a transparent polyimide film.

The second adhesive member ADH2 may be arranged on a rear surface of the window member 200. For example, the second adhesive member ADH2 may be arranged between the window member 200 and the optical member 300. The window member 200 and the optical member 300 may be coupled to each other through the second adhesive member ADH2. The second adhesive member ADH2 may include an optical clear resin (OCR). For example, in one or more embodiments, the second adhesive member ADH2 may include an acrylic adhesive material as an OCR. In one or more embodiments, the second adhesive member ADH2 may be formed by being provided in a liquid form on the optical member 300 (or the display panel 400) and then cured.

The upper protective member 100 may be arranged on a front surface of the window member 200. The upper protective member 100 may perform at least one function selected from among prevention of scattering, impact absorption, prevention of scratch, prevention of fingerprint smudges, and prevention of glare on the window member 200.

In one or more embodiments, as illustrated in FIG. 6, the upper protective member 100 may include a base layer 110 and a coating layer 120 arranged on the base layer 110. The base layer 110 may include at least one of polyacrylate, polyethylene terephthalate (PET), polyimide (PI), cycloolefin polymer, triacetyl cellulose (TAC), polycarbonate (PC), epoxy, or polymethyl methacrylate (PMMA). The coating layer 120 may be a layer formed by coating a top surface of the base layer 110. The coating layer 120 may perform at least one function selected from among prevention of scattering, shock absorption, prevention of scratch, prevention of fingerprint smudges, and prevention of glare on the window 220.

The first adhesive member ADH1 may be arranged on a rear surface of the upper protective member 100. For example, the first adhesive member ADH1 may be arranged between the upper protective member 100 and the window member 200. The upper protective member 100 and the window member 200 may be coupled to each other through the first adhesive member ADH1. The first adhesive member ADH1 may include an OCR. For example, in one or more embodiments, the first adhesive member ADH1 may include an acrylic adhesive material as an OCR. In one or more embodiments, the first adhesive member ADH1 may be formed by being provided in a liquid form on the window member 200 and then cured.

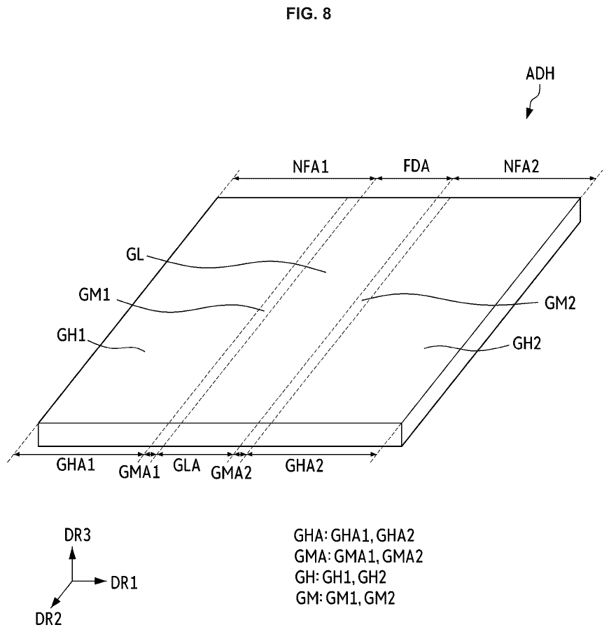

In one or more embodiments, the first adhesive member ADH1 and the second adhesive member ADH2 may be included in an adhesive member ADH. The adhesive member ADH will be described in more detail later with reference to FIG. 8 and/or the like.

The panel protection member 500 may be arranged on a back surface of the display panel 400. The panel protection member 500 may serve to support the display panel 400 and protect the back surface of the display panel 400. The panel protection member 500 may be made of plastic (e.g., a polymer) such as polyethylene terephthalate (PET) and/or polyimide. Although the drawing illustrates that the panel protection member 500 is also arranged in the folding area FDA of the display device 10, embodiments of the present disclosure are not limited thereto. For example, in one or more embodiments, the panel protection member 500 may be removed from the folding area FDA of the display device 10 so that the display device 10 may be smoothly folded.

The panel lower member 600 may be arranged on a rear surface of the panel protection member 500. The panel lower member 600 may include at least one of a light blocking layer for absorbing light incident from the outside, a buffer layer for absorbing an impact from the outside, or a heat dissipation layer for efficiently dissipating heat from the display panel 400.

The light blocking layer blocks the transmission of light, and thus prevents (or protects from) components, for example, the digitizer member 900 and/or the like, arranged below the light blocking layer from being visually recognized at the upper side of the display panel 400. The light blocking layer may include a light absorbing material such as a black pigment, black dyes and/or the like.

The buffer layer absorbs an external impact to prevent or reduce the display panel 400 from being damaged. The buffer layer may be formed of a single layer or multiple layers. For example, in one or more embodiments, the buffer layer may be formed of a polymer resin such as polyurethane (PU), polycarbonate (PC), polypropylene (PP), and/or polyethylene (PE) and/or may include an elastic material such as sponge obtained by foam-molding a rubber, a urethane-based material, and/or an acrylic-based material.

The heat dissipation layer may include a first heat dissipation layer containing graphite, carbon nanotubes and/or the like, and a second heat dissipation layer formed of a metal thin film containing, for example, copper, nickel, ferrite, and/or silver which can shield electromagnetic waves and has excellent or suitable thermal conductivity.

In one or more embodiments, the panel lower member 600 may not be provided.

The panel support member 700 may be arranged on a rear surface of the panel lower member 600. The panel support member 700 may be a rigid member of which shape or volume does not easily change under external pressure. The panel support member 700 may be arranged on the rear surface of the display panel 400, and may support the display panel 400 because the panel support member 700 is a rigid member of which shape or volume does not easily change under external pressure.

In one or more embodiments, the panel support member 700 may include (e.g., be) a polymer containing carbon fiber and/or glass fiber. In these embodiments, the panel support member 700 is made of a polymer including carbon fiber and/or glass fiber, and thus may enable the magnetic field and/or electromagnetic signal of the digitizer member 900 to pass therethrough. Accordingly, the panel support member 700 that may enable the touch sensitivity of the digitizer member 900 not to be lowered and may concurrently (e.g., simultaneously) support the display panel 400 may be provided.

In one or more embodiments, the panel support member 700 may be a metal plate. For example, the panel support member 700 may be made of a metal or a metal alloy as the metal plate. The panel support member 700 may include copper (Cu), aluminum (AI), stainless steel (SUS), and/or an alloy thereof, but embodiments of the present disclosure are not limited thereto.

The panel support member 700 may include a through hole STH that overlaps the optical device OPD in the third direction DR3. The through hole STH may overlap the light transmission area LTA of the display panel 400 in the third direction DR3. The area of the through hole STH may be greater than the area of the light transmission area LTA. The optical device OPD may sense light incident from the front surface of the display device 10 through the light transmission area LTA and the through hole STH.

The panel support member 700 may include a grid pattern arranged in the folding area FDA to be easily bent in the folding area FDA. The panel support member 700 includes the grid pattern arranged in the folding area FDA, so that the panel support member 700 may be easily bent if (e.g., when) the display device 10 is folded.

The lower visibility prevention member LPU may be arranged on a rear surface of the panel support member 700. The lower visibility prevention member LPU may be arranged to overlap the folding area FDA. The lower visibility prevention member LPU may be arranged in the same layer as the third adhesive member 800. The lower visibility prevention member LPU may be arranged between a third-first adhesive member 810 and a third-second adhesive member 820, for example, in the second direction DR2. The lower visibility prevention member LPU may prevent or reduce the grid pattern of the panel support member 700 from being visually recognized to the outside. The lower visibility prevention member LPU may include a flexible material to reduce folding stress of the display device 10.

The third adhesive member 800 may be arranged on a front surface of the digitizer member 900. For example, the third adhesive member 800 may be arranged between the panel support member 700 and the digitizer member 900. The panel support member 700 and the digitizer member 900 may be coupled to each other through the third adhesive member 800. The third adhesive member 800 may include (e.g., be) a clear adhesive such as a pressure sensitive adhesive (PSA) and/or an optically clear adhesive (OCA).

In one or more embodiments, the third adhesive member 800 may include the third-first adhesive member 810 overlapping a first digitizer member 910 and the third-second adhesive member 820 overlapping a second digitizer member 920. The third-first adhesive member 810 and the third-second adhesive member 820 may be arranged to be spaced and/or apart (e.g., spaced apart or separated) from each other with the lower visibility prevention member LPU interposed therebetween.

The digitizer member 900 may include the first digitizer member 910 and the second digitizer member 920. The first digitizer member 910 and the second digitizer member 920 may be arranged on the rear surface of the panel support member 700. The first digitizer member 910 and the second digitizer member 920 may be attached to the rear surface of the panel support member 700 by the third adhesive member 800.

The first digitizer member 910 and the second digitizer member 920 may not be arranged in the folding area FDA to reduce folding stress of the display device 10. The first digitizer member 910 may be arranged in the first non-folding area NFA1, and the second digitizer member 920 may be arranged in the second non-folding area NFA2. A gap between the first digitizer member 910 and the second digitizer member 920 may overlap the folding area FDA and may be less than a width of the folding area FDA. The width of the folding area FDA may be the length of the folding area FDA in the second direction DR2.

In one or more embodiments, the first digitizer member 910 and the second digitizer member 920 may each include electrode patterns for detecting the approach or contact of an electronic pen such as a stylus pen that supports an electromagnetic resonance (EMR) method. The first digitizer member 910 and the second digitizer member 920 may detect a magnetic field or electromagnetic signal emitted from the electronic pen by the electrode patterns, and determine a point at which the detected magnetic field or electromagnetic signal is largest as a touch coordinate.

In one or more embodiments, magnetic metal powder may be arranged in a rear surface of the first digitizer member 910 and a rear surface of the second digitizer member 920. In these embodiments, a magnetic field or electromagnetic signal that has passed through the first digitizer member 910 and the second digitizer member 920 may be enabled to flow into the interior of the magnetic metal powder. Accordingly, due to the magnetic metal powder, the magnetic field or electromagnetic signal of the first digitizer member 910 and the second digitizer member 920 may be hindered from being emitted to a rear surface of the display device 10.

The metal support member 1000 may include a first metal support member 1010 and a second metal support member 1020. The first metal support member 1010 may be arranged on the rear surface of the first digitizer member 910, and the second metal support member 1020 may be arranged on the rear surface of the second digitizer member 920.

The first metal support member 1010 and the second metal support member 1020 may not be arranged in the folding area FDA to reduce the folding stress of the display device 10. The first metal support member 1010 may be arranged in the first non-folding area NFA1, and the second metal support member 1020 may be arranged in the second non-folding area NFA2. A gap between the first metal support member 1010 and the second metal support member 1020 may overlap the folding area FDA and may be less than the width of the folding area FDA.

The first metal support member 1010 and the second metal support member 1020 may each include a material having high rigidity to support the first digitizer member 910 and the second digitizer member 920. For example, in one or more embodiments, the first metal support member 1010 and the second metal support member 1020 may each include stainless steel such as SUS316.

The buffer member 1100 may include a first buffer member 1110 and a second buffer member 1120. The first buffer member 1110 and the second buffer member 1120 may be to absorb external impact and prevent or reduce the panel support member 700 and the digitizer member 900 from being damaged. The first buffer member 1110 and the second buffer member 1120 may each include an elastic material such as sponge obtained by foam-molding a rubber, a urethane-based material, or an acrylic-based material.

The first buffer member 1110 may be arranged on a rear surface of the first metal support member 1010, and the second buffer member 1120 may be arranged on a rear surface of the second metal support member 1020. The first buffer member 1110 and the second buffer member 1120 may not be arranged in the folding area FDA to reduce the folding stress of the display device 10. The first buffer member 1110 may be arranged in the first non-folding area NFA1, and the second buffer member 1120 may be arranged in the second non-folding area NFA2. A gap between the first buffer member 1110 and the second buffer member 1120 may overlap the folding area FDA and may be less than the width of the folding area FDA.

The fourth adhesive member 1200 may be arranged on a rear surface of the first metal support member 1010 and a rear surface of the second metal support member 1020. The fourth adhesive member 1200 may be arranged at an edge of the first metal support member 1010 and an edge of the second metal support member 1020. In FIG. 5 and FIG. 6, the fourth adhesive member 1200 is illustrated as being arranged on sides of both the first buffer member 1110 and the second buffer member 1120, but embodiments of the present disclosure are not limited thereto. For example, in one or more embodiments, the fourth adhesive member 1200 may be arranged to be around (e.g., surround) the first buffer member 1110 and the second buffer member 1120.

The fourth adhesive member 1200 may be a waterproof tape or a waterproof member that attaches the rear surface of the first metal support member 1010 to a front surface of a frame arranged on the rear surface of the buffer member 1100. Accordingly, moisture and/or dust may be prevented or reduced from permeating into the display device 10 by the fourth adhesive member 1200. For example, the display device 10 that is waterproof and dustproof may be provided.

In one or more embodiments, the fourth adhesive member 1200 may not be around (e.g., surround) the first buffer member 1110 and the second buffer member 1120 and may be arranged to overlap magnets for maintaining folding of the display device 10 in the third direction DR3. In these embodiments, the fourth adhesive member 1200 may serve as a magnetic shielding member that may shield magnetism to prevent or reduce the digitizer member 900 or the display panel 400 from being affected by the magnetism of the magnet.

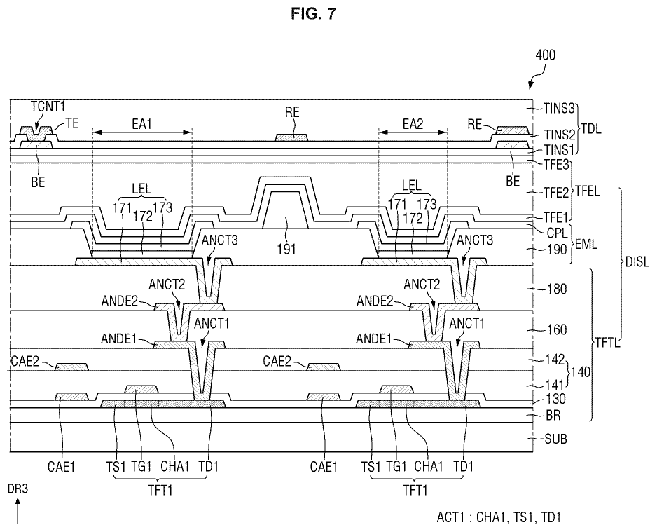

FIG. 7 is a cross-sectional view illustrating an example of a display panel according to one or more embodiments of the present disclosure.

Referring to FIG. 7, a display panel 400 may include a substrate SUB, a display layer DISL arranged on the substrate SUB, and a touch sensing layer TDL arranged on the display layer DISL. The display layer DISL may include a thin film transistor layer TFTL, a light emitting element layer EML, and an encapsulation layer TFEL.

The thin film transistor layer TFTL may be arranged on the substrate SUB. The thin film transistor layer TFTL may include a barrier film BR, a thin film transistor TFT1, a first capacitor electrode CAE1, a second capacitor electrode CAE2, a first anode connection electrode ANDE1, a second anode connection electrode ANDE2, a gate insulating film 130, an interlayer insulating film 140, a first planarization film 160, and a second planarization film 180. In one or more embodiments, the interlayer insulating film 140 may include a first interlayer insulating film 141 and a second interlayer insulating film 142.

The substrate SUB may be formed of an insulating material such as a polymer resin. For example, in one or more embodiments, the substrate SUB may be formed of a polyimide. The substrate SUB may be a flexible substrate which can be bent, folded, or rolled.

The barrier film BR may be arranged on the substrate SUB. The barrier film BR is a film for protecting thin film transistors of the thin film transistor layer TFTL and a light emitting layer 172 of the light emitting element layer EML from moisture permeating through the substrate SUB which may be susceptible to moisture permeation. In one or more embodiments, the barrier film BR may be formed as a plurality of inorganic films that are alternately stacked. For example, in one or more embodiments, the barrier film BR may be formed of multiple films in which one or more inorganic films selected from among a silicon nitride layer, a silicon oxynitride layer, a silicon oxide layer, a titanium oxide layer, and an aluminum oxide layer are alternately stacked.

The thin film transistor TFT1 may be arranged on the barrier film BR. An active layer ACT1 of the thin film transistor TFT1 may be arranged on the barrier film BR. The active layer ACT1 of the thin film transistor TFT1 may include polycrystalline silicon, monocrystalline silicon, low-temperature polycrystalline silicon, amorphous silicon, or an oxide semiconductor.

The active layer ACT1 may include a channel region CHA1, a source region TS1, and a drain region TD1. The channel region CHA1 may be a region overlapping a gate electrode TG1 in the third direction DR3 that is a thickness direction of the substrate SUB. The source region TS1 may be arranged on one side of the channel region CHA1, and the drain region TD1 may be arranged on the other side of the channel region CHA1. The source region TS1 and the drain region TD1 may be regions that do not overlap the gate electrode TG1 in the third direction DR3. The source region TS1 and the drain region TD1 may be regions having conductivity by doping a silicon semiconductor or an oxide semiconductor with ions or impurities.

The gate insulating film 130 may be arranged on the active layer ACT1 of the thin film transistor TFT1. The gate insulating film 130 may be formed of an inorganic film, for example, a silicon nitride layer, a silicon oxynitride layer, a silicon oxide layer, a titanium oxide layer, or an aluminum oxide layer.

The gate electrode TG1 of the thin film transistor TFT1 and the first capacitor electrode CAE1 may be arranged on the gate insulating film 130. The gate electrode TG1 may overlap the channel region CHA1 in the third direction DR3. FIG. 7 illustrates that the gate electrode TG1 and the first capacitor electrode CAE1 are spaced and/or apart (e.g., spaced apart or separated) from each other, but, in one or more embodiments, the gate electrode TG1 and the first capacitor electrode CAE1 may be connected to each other and formed integrally. The gate electrode TG1 and the first capacitor electrode CAE1 may be each formed as a single layer or multiple layers made of any one selected from among molybdenum (Mo), aluminum (AI), chromium (Cr), gold (Au), titanium (Ti), nickel (Ni), neodymium (Nd), and copper (Cu) or an alloy thereof.

The first interlayer insulating film 141 may be arranged on the gate electrode TG1 of the thin film transistor TFT1 and the first capacitor electrode CAE1. In one or more embodiments, the first interlayer insulating film 141 may be formed of an inorganic film, for example, a silicon nitride layer, a silicon oxynitride layer, a silicon oxide layer, a titanium oxide layer, or an aluminum oxide layer. In one or more embodiments, the first interlayer insulating film 141 may be formed of a plurality of inorganic films.

The second capacitor electrode CAE2 may be arranged on the first interlayer insulating film 141. The second capacitor electrode CAE2 may overlap the first capacitor electrode CAE1 in the third direction DR3. Further, in one or more embodiments, if (e.g., when) the gate electrode TG1 and the first capacitor electrode CAE1 are formed integrally, the second capacitor electrode CAE2 may overlap the gate electrode TG1 in the third direction DR3. Because the first interlayer insulating film 141 has a set or predetermined dielectric constant, a capacitor may be formed by the first capacitor electrode CAE1, the second capacitor electrode CAE2, and the first interlayer insulating film 141 arranged therebetween. The second capacitor electrode CAE2 may be formed of a single layer or multiple layers made of any one selected from among molybdenum (Mo), aluminum (Al), chromium (Cr), gold (Au), titanium (Ti), nickel (Ni), neodymium (Nd), and copper (Cu), or an alloy thereof.

The second interlayer insulating film 142 may be arranged on the second capacitor electrode CAE2. In one or more embodiments, the second interlayer insulating film 142 may be formed of an inorganic film, for example, a silicon nitride layer, a silicon oxynitride layer, a silicon oxide layer, a titanium oxide layer, or an aluminum oxide layer. In one or more embodiments, the second interlayer insulating film 142 may be formed of a plurality of inorganic films.

The first anode connection electrode ANDE1 may be arranged on the second interlayer insulating film 142. The first anode connection electrode ANDE1 may be connected to the drain region TD1 of the thin film transistor TFT1 through a first connection contact hole ANCT1 penetrating the gate insulating film 130, the first interlayer insulating film 141, and the second interlayer insulating film 142. The first anode connection electrode ANDE1 may be formed as a single layer or multiple layers made of any one selected from among molybdenum (Mo), aluminum (Al), chromium (Cr), gold (Au), titanium (Ti), nickel (Ni), neodymium (Nd), and copper (Cu), or an alloy thereof.

The first planarization film 160 for flattening a stepped (e.g., an uneven) portion formed by the thin film transistor TFT1 may be arranged on the first anode connection electrode ANDE1. The first planarization film 160 may be formed of an organic film such as an acryl resin, an epoxy resin, a phenolic resin, a polyamide resin, a polyimide resin, and/or the like.

The second anode connection electrode ANDE2 may be arranged on the first planarization film 160. The second anode connection electrode ANDE2 may be connected to the first anode connection electrode ANDE1 through a second connection contact hole ANCT2 penetrating the first planarization film 160. The second anode connection electrode ANDE2 may be formed as a single layer or multiple layers made of any one selected from among molybdenum (Mo), aluminum (Al), chromium (Cr), gold (Au), titanium (Ti), nickel (Ni), neodymium (Nd), and copper (Cu), or an alloy thereof.

The second planarization film 180 may be arranged on the second anode connection electrode ANDE2. The second planarization film 180 may be formed of an organic film such as an acryl resin, an epoxy resin, a phenolic resin, a polyamide resin, a polyimide resin, and/or the like.

The light emitting element layer EML including light emitting elements LEL and a bank 190 may be arranged on the second planarization film 180. Each of the light emitting elements LEL may include a pixel electrode 171, the light emitting layer 172, and a common electrode 173.

The pixel electrode 171 may be arranged on the second planarization film 180. The pixel electrode 171 may be connected to the second anode connection electrode ANDE2 through a third connection contact hole ANCT3 penetrating the second planarization film 180.

In a top emission structure that emits light toward the common electrode 173 with respect to the light emitting layer 172, the pixel electrode 171 may be made of a metal material having high reflectivity such as a stacked structure (Ti/AI/Ti) of aluminum (AI) and titanium (Ti), a stacked structure (ITO/AI/ITO) of aluminum (AI) and indium tin oxide (ITO), a stacked structure (ITO/Ag/ITO) of silver (Ag) and ITO, an APC alloy, and a stacked structure (ITO/APC/ITO) of an APC alloy and ITO. The APC alloy is an alloy of silver (Ag), palladium (Pd), and copper (Cu).

The bank 190 may be formed to partition the pixel electrode 171 on the second planarization film 180, in order to define emission portions EA1 and EA2. The bank 190 may be arranged to cover an edge of the pixel electrode 171. The bank 190 may be formed of an organic film such as an acryl resin, an epoxy resin, a phenolic resin, a polyamide resin, a polyimide resin, and/or the like.

Each of a first emission portion EA1 and a second emission portion EA2 represents an area in which the pixel electrode 171, the light emitting layer 172, and the common electrode 173 are sequentially stacked, and holes from the pixel electrode 171 and electrons from the common electrode 173 are recombined in the light emitting layer 172 to emit light.

In one or more embodiments, the light emitting layer 172 may be arranged on the pixel electrode 171. In one or more embodiments, the light emitting layer 172 may be arranged on the pixel electrode 171 and the bank 190. The light emitting layer 172 may include an organic material to emit light in a set or predetermined color. For example, in one or more embodiments, the light emitting layer 172 may include a hole transporting layer, an organic material layer, and an electron transporting layer.

The common electrode 173 may be arranged on the light emitting layer 172. The common electrode 173 may be arranged to cover the light emitting layer 172. The common electrode 173 may be a common layer formed commonly in the first emission portion EA1 and the second emission portion EA2.

In the top emission structure, the common electrode 173 may be formed of a transparent conductive material (TCO) such as indium tin oxide (ITO) and/or indium zinc oxide (IZO) capable of transmitting light or a semi-transmissive conductive material such as magnesium (Mg), silver (Ag), or an alloy of magnesium (Mg) and silver (Ag). When the common electrode 173 is formed of a semi-transmissive conductive material, the light emission efficiency can be increased due to a micro-cavity effect.

A spacer 191 may be arranged on the bank 190. The spacer 191 may serve to support a mask during a fabrication process of fabricating the light emitting layer 172. The spacer 191 may be formed of an organic film such as an acryl resin, an epoxy resin, a phenolic resin, a polyamide resin, a polyimide resin, and/or the like.

In one or more embodiments, the display panel 400 may further include a capping layer CPL arranged on the common electrode 173. The capping layer CPL may include an inorganic material. For example, in one or more embodiments, the capping layer CPL may contain at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride.

The encapsulation layer TFEL may be arranged on the common electrode 173. The encapsulation layer TFEL may include at least one inorganic film to prevent or reduce oxygen and/or moisture from permeating into the light emitting element layer EML. In addition, the encapsulation layer TFEL may include at least one organic film to protect the light emitting element layer EML from foreign substances such as dust. For example, in one or more embodiments, the encapsulation layer TFEL may include a first encapsulation inorganic film TFE1, an encapsulation organic film TFE2, and a second encapsulation inorganic film TFE3.

The first encapsulation inorganic film TFE1 may be arranged on the common electrode 173, the encapsulation organic film TFE2 may be arranged on the first encapsulation inorganic film TFE1, and the second encapsulation inorganic film TFE3 may be arranged on the encapsulation organic film TFE2. The first encapsulation inorganic film TFE1 and the second encapsulation inorganic film TFE3 may be each formed of multiple films in which one or more inorganic films selected from among a silicon nitride layer, a silicon oxynitride layer, a silicon oxide layer, a titanium oxide layer, and an aluminum oxide layer are alternately stacked. The encapsulation organic film TFE2 may be an organic film such as an acryl resin, an epoxy resin, a phenolic resin, a polyamide resin, a polyimide resin, and/or the like.

The touch sensing layer TDL may be arranged on the encapsulation layer TFEL. The touch sensing layer TDL may include a first touch insulating film TINS1, a connection electrode BE, a second touch insulating film TINS2, a driving electrode TE, a sensing electrode RE, and a third touch insulating film TINS3.

The first touch insulating film TINS1 may be arranged on the encapsulation layer TFEL. The first touch insulating film TINS1 may be formed of an inorganic film, for example, a silicon nitride layer, a silicon oxynitride layer, a silicon oxide layer, a titanium oxide layer, or an aluminum oxide layer.

The connection electrode BE may be arranged on the first touch insulating film TINS1. The connection electrode BE may be formed as a single layer or multiple layers made of any one selected from among molybdenum (Mo), aluminum (AI), chromium (Cr), gold (Au), titanium (Ti), nickel (Ni), neodymium (Nd), and copper (Cu), or an alloy thereof.

The second touch insulating film TINS2 may be arranged on the connection electrode BE. In one or more embodiments, the second touch insulating film TINS2 may be formed of an inorganic film, for example, a silicon nitride layer, a silicon oxynitride layer, a silicon oxide layer, a titanium oxide layer, or an aluminum oxide layer. In one or more embodiments, the second touch insulating film TINS2 may be formed of an organic film such as an acryl resin, an epoxy resin, a phenolic resin, a polyamide resin, a polyimide resin, and/or the like.

The driving electrodes TE and the sensing electrodes RE may be arranged on the second touch insulating film TINS2. The driving electrodes TE and the sensing electrodes RE may be each formed as a single layer or multiple layers made of any one selected from among molybdenum (Mo), aluminum (Al), chromium (Cr), gold (Au), titanium (Ti), nickel (Ni), neodymium (Nd), and copper (Cu), or an alloy thereof.

The driving electrode TE and the sensing electrode RE may overlap the connection electrode BE in the third direction DR3. The driving electrode TE may be connected to the connection electrode BE through a touch contact hole TCNT1 penetrating the second touch insulating film TINS2.

The third touch insulating film TINS3 may be formed on the driving electrodes TE and the sensing electrodes RE. The third touch insulating film TINS3 may serve to flatten the stepped (e.g., uneven) portion formed by the driving electrodes TE, the sensing electrodes RE, and the connection electrodes BE. The third touch insulating film TINS3 may be formed of an organic film such as an acryl resin, an epoxy resin, a phenolic resin, a polyamide resin, a polyimide resin, and/or the like.

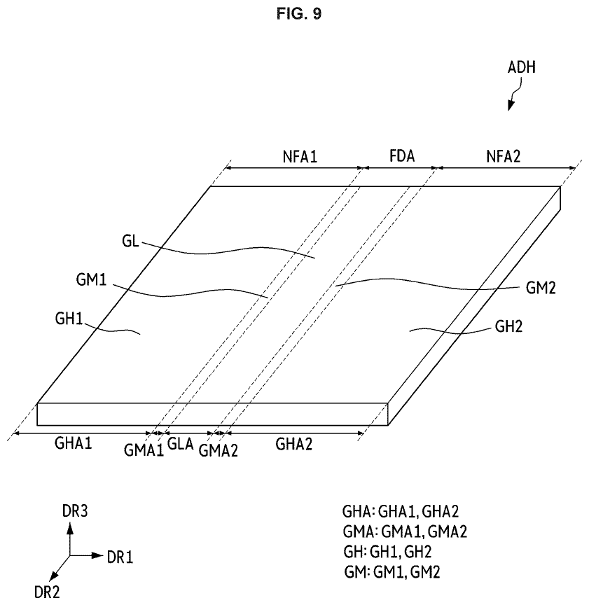

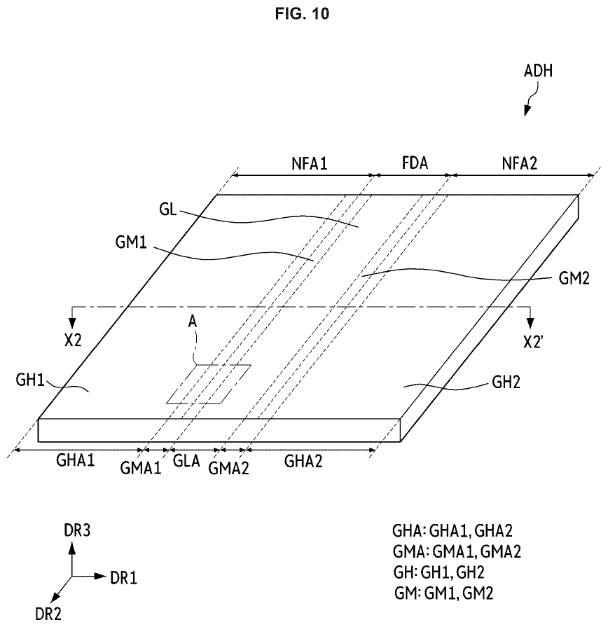

FIG. 8 is a plan view showing an example of an adhesive member according to one or more embodiments of the present disclosure. FIG. 9 is a plan view showing another example of an adhesive member according to one or more embodiments of the present disclosure. FIG. 10 is a plan view showing still another example of an adhesive member according to one or more embodiments of the present disclosure.

Referring to FIGS. 8 to 10 in addition to FIGS. 5 and 6, the adhesive member ADH may include a high-rigidity area GHA, a low-rigidity area GLA, and a mixed area GMA.

The low-rigidity area GLA may overlap the folding area FDA. The low-rigidity area GLA may be arranged generally centrally in the first direction DR1, e.g., generally centered in the first direction DR1 in the folding area FDA. In one or more embodiments, as illustrated in FIG. 8, the low-rigidity area GLA may coincide with the folding area FDA. In one or more embodiments, as illustrated in FIGS. 9 and 10, the low-rigidity area GLA may be less than (e.g., narrower than) the folding area FDA in the first direction DR1. In one or more embodiments, the low-rigidity area GLA may be greater than (e.g., wider than) the folding area FDA in the first direction DR1.

The high-rigidity area GHA may overlap the non-folding areas NFA1 and NFA2. The high-rigidity area GHA may be arranged on at least one side of the low-rigidity area GLA. For example, in one or more embodiments, the high-rigidity area GHA may include a first high-rigidity area GHA1 arranged on the other side of the low-rigidity area GLA in the first direction DR1 and a second high-rigidity area GHA2 arranged on one side thereof in the first direction DR1.

In one or more embodiments, as illustrated in FIGS. 8 and 10, the first high-rigidity area GHA1 and the second high-rigidity area GHA2 may be less than (e.g., narrower than) the first non-folding area NFA1 and the second non-folding area NFA2 in the first direction DR1, respectively. In one or more embodiments, as illustrated in FIG. 9, the first high-rigidity area GHA1 and the second high-rigidity area GHA2 may coincide with the first non-folding area NFA1 and the second non-folding area NFA2, respectively. In one or more embodiments, the first high-rigidity area GHA1 and the second high-rigidity area GHA2 may be greater than (e.g., wider than) the first non-folding area NFA1 and the second non-folding area NFA2 in the second direction DR2, respectively.

The mixed area GMA may be arranged between the low-rigidity area GLA and the high-rigidity area GHA. For example, in one or more embodiments, the mixed area GMA may include a first mixed area GMA1 arranged between the first high-rigidity area GHA1 and the low-rigidity area GLA, and a second mixed area GMA2 arranged between the second high-rigidity area GHA2 and the low-rigidity area GLA.

In one or more embodiments, as illustrated in FIG. 8, the first mixed area GMA1 may overlap the first non-folding area NFA1, and the second mixed area GMA2 may overlap the second non-folding area NFA2. In one or more embodiments, as illustrated in FIG. 9, the first mixed area GMA1 and the second mixed area GMA2 may each only overlap the folding area FDA. In one or more embodiments, as illustrated in FIG. 10, the first mixed area GMA1 may overlap the first non-folding area NFA1 and the folding area FDA, and the second mixed area GMA2 may overlap t the folding area FDA and the second non-folding area NFA2.

Hereinafter, one or more embodiments of FIG. 10 will be described as an example, but embodiments of the present disclosure are not limited thereto.

The adhesive member ADH may include a low-rigidity portion GL (e.g., arranged in the low-rigidity area GLA), a high-rigidity portion GH (e.g., arranged in the high-rigidity area GHA), and a mixed portion GM. In the disclosure, each of the low-rigidity portion GL, the high-rigidity portion GH, and the mixed portion GM is separately described, but they may be an integral configuration in which they are physically coupled.

The low-rigidity portion GL may be arranged in the low-rigidity area GLA. The low-rigidity portion GL may be arranged generally centrally in the first direction DR1 in the low-rigidity area GLA.

The high-rigidity portion GH may be arranged in the high-rigidity area GHA. The high-rigidity portion GH may be arranged on at least one side of the low-rigidity portion GL. For example, in one or more embodiments, the high-rigidity portion GH may include a first high-rigidity portion GH1 arranged in the first high-rigidity area GHA1 and a second high-rigidity portion GH2 arranged in the second high-rigidity area GHA2. The first high-rigidity portion GH1 may be arranged on the other side of the low-rigidity portion GL in the first direction DR1 and the second high-rigidity portion GH2 may be arranged on one side of the low-rigidity portion GL in the first direction DR1.

The mixed portion GM may be arranged in the mixed area GMA. The mixed portion GM may be arranged between the low-rigidity portion GL and the high-rigidity portion GH. For example, in one or more embodiments, the mixed portion GM may include a first mixed portion GM1 arranged between the first high-rigidity portion GH1 and the low-rigidity portion GL, and a second mixed portion GM2 arranged between the second high-rigidity portion GH2 and the low-rigidity portion GL.

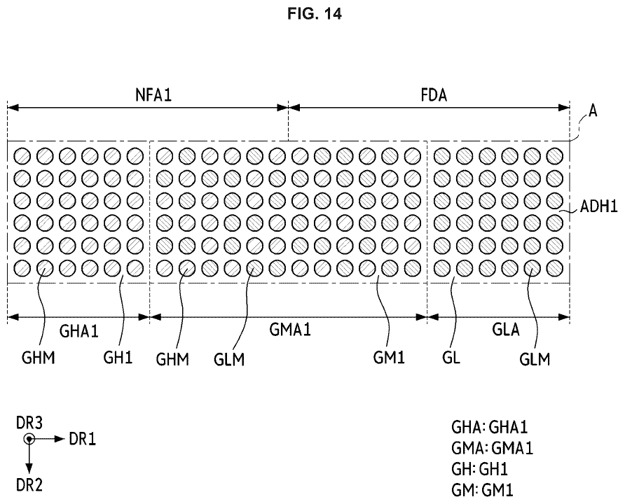

The low-rigidity portion GL and the high-rigidity portion GH may include different materials. For example, a material (e.g., a resin) included in the low-rigidity portion GL and a material (e.g., a resin) included in the high-rigidity portion GH may have different moduli. The mixed portion GM may include a mixture of the material included in the low-rigidity portion GL and the material included in the high-rigidity portion GH. Regarding the materials included in the low-rigidity portion GL, the high-rigidity portion GH, and the mixed portion GM, descriptions will be provided later with reference to FIG. 14 and/or the like.

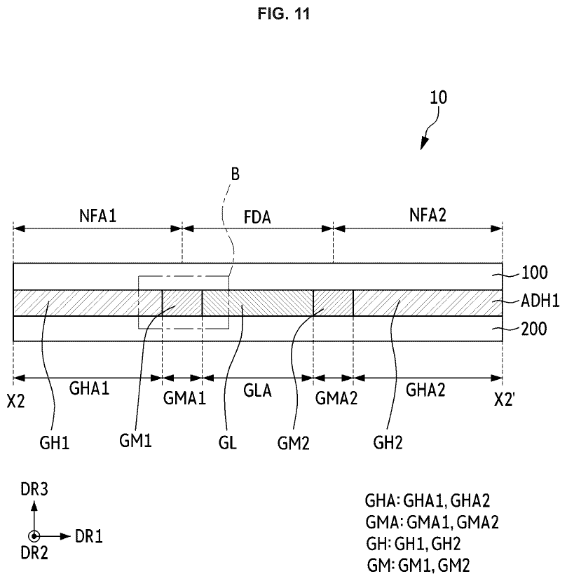

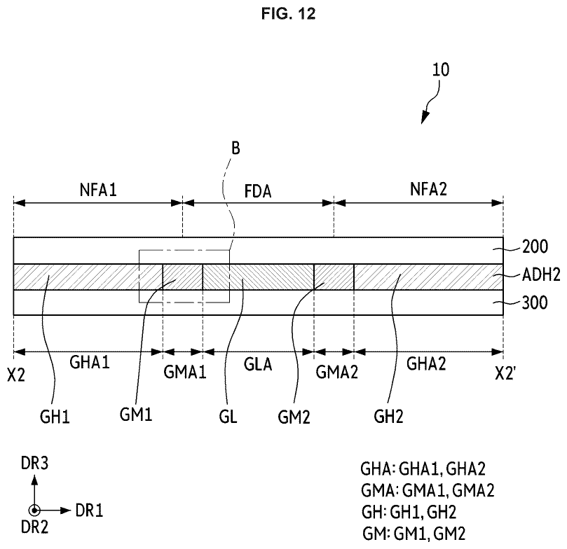

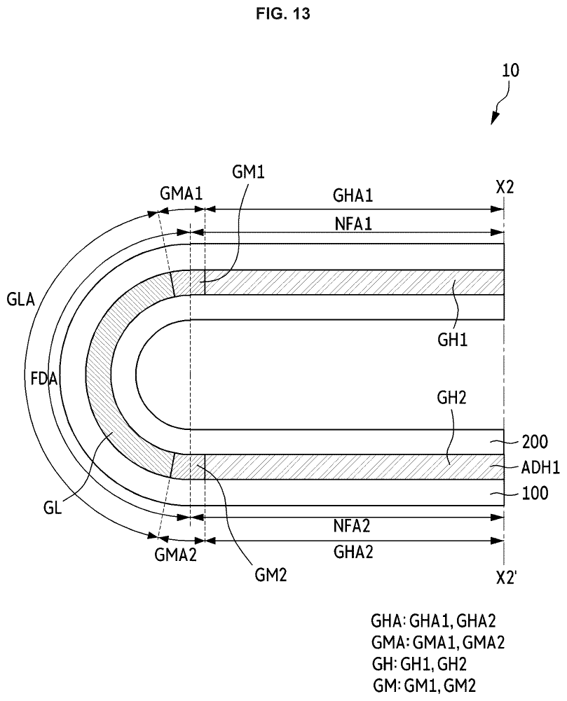

FIG. 11 is a cross-sectional view showing an example of a cross-section of a display device taken along the line X2-X2′ of FIG. 10 according to one or more embodiments of the present disclosure. FIG. 12 is a cross-sectional view showing an example of a cross-section of a display device taken along the line X2-X2′ of FIG. 10 according to one or more embodiments of the present disclosure. FIG. 13 is a cross-sectional view showing a folded state of the display device of FIG. 11 according to one or more embodiments.

In FIG. 10, only the adhesive member ADH is illustrated, but in FIGS. 11 to 13, the components attached to top and bottom surfaces of the adhesive member ADH are also illustrated for simplicity of description.

Referring to FIGS. 11 to 13 in addition to FIGS. 5, 6, and 8 to 10, the adhesive member ADH may include a first adhesive member ADH1 and a second adhesive member ADH2. As illustrated in FIG. 11, the first adhesive member ADH1 may be arranged between the upper protective member 100 and the window member 200, and as illustrated in FIG. 12, the second adhesive member ADH2 may be arranged between the window member 200 and the optical member 300. In one or more embodiments, if (e.g., when) the optical member 300 is omitted or mounted in the display panel 400, the second adhesive member ADH2 may be arranged between the window member 200 and the display panel 400.

Because the first adhesive member ADH1 and the second adhesive member ADH2 share substantially the same technical idea except for the configuration of being attached to the top and bottom surfaces of the window member 200, the first adhesive member ADH1 will be mainly described in more detail. The second adhesive member ADH2 may be applied with the same technical idea as the first adhesive member ADH1 described.

As illustrated in FIG. 13, the display device 10 may be folded in the folding area FDA. The display device 10 according to the present embodiment may have improved foldability by including the low-rigidity portion GL having a low modulus.

In the present disclosure, modulus may relate to deformation or restoration in response to a pressure applied to the adhesive member ADH. The modulus is expressed as a ratio of stress to strain, and a smaller modulus indicates easier deformation at the same stress level. In the present disclosure, modulus refers to elastic modulus, which refers to Young's modulus. The modulus may be measured by an indenter, such as a bio-indenter or a nano-indenter, made by the company Anton-Paar GmbH. For example, in one or more embodiments, the modulus may be measured by an indenter evaluation method.

The low-rigidity portion GL may have a lower modulus than the high-rigidity portion GH. The modulus of the low-rigidity portion GL refers to an average modulus of the low-rigidity portion GL, and the modulus of the high-rigidity portion GH refers to an average modulus of the high-rigidity portion GH. For example, in one or more embodiments, the modulus of the low-rigidity portion GL may be approximately (about) 0.03 MPa to about 1 MPa, and the modulus of the high-rigidity portion GH may be approximately (about) 1.5 MPa or more.

The modulus of the mixed portion GM may be greater than the modulus of the low-rigidity portion GL but less than the modulus of the high-rigidity portion GH. For example, in one or more embodiments, the modulus of the mixed portion GM may be approximately (about) 0.5 MPa to about 1.5 MPa.

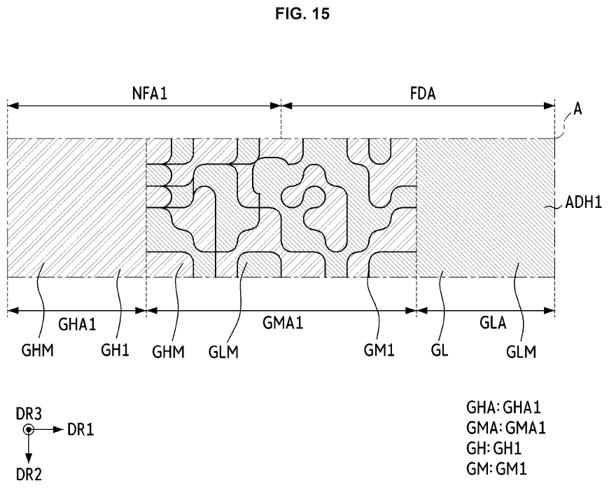

Meanwhile, the display device 10 according to the present embodiment may improve the thickness uniformity of the adhesive member ADH by including the mixed portion GM in which the material of the low-rigidity portion GL and the material of the high-rigidity portion GH are evenly mixed. Accordingly, the adhesion of the adhesive member ADH may be improved. This will be described with reference to FIGS. 14 and 15.

FIG. 14 is an enlarged schematic diagram illustrating area A of FIG. 10 according to one or more embodiments of the present disclosure. FIG. 15 is an enlarged plan view illustrating area A of FIG. 10 according to one or more embodiments of the present disclosure.

Referring to FIGS. 14 and 15 in addition to FIGS. 8 to 13, the low-rigidity portion GL and the high-rigidity portion GH may include different materials. For example, in one or more embodiments, the low-rigidity portion GL may include a first resin GLM, and the high-rigidity portion GH may include a second resin GHM. The second resin GHM may have a higher modulus than the first resin GLM.

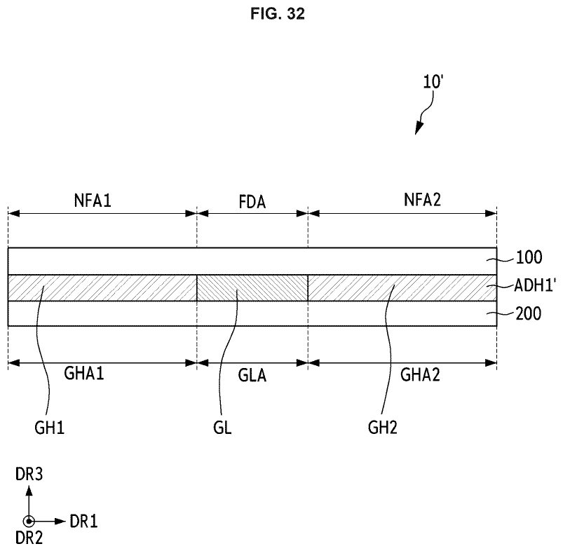

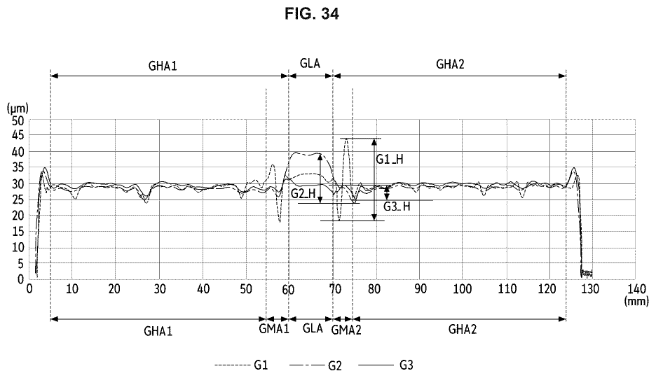

The mixed portion GM may include both (e.g., simultaneously) the first resin GLM and the second resin GHM. Because the display device 10 according to the present embodiment includes the mixed portion GM, a phenomenon of thickness unevenness that may occur at a boundary surface between the low-rigidity portion GL and the high-rigidity portion GH if (e.g., when) the low-rigidity portion GL and the high-rigidity portion GH are in direct contact with each other without including the mixed portion GM, may be mitigated. For example, in one or more embodiments, a thickness deviation of the adhesive member ADH may be within approximately (about) 5 μm. This will be described in more detail later with reference to FIGS. 32 and 34.

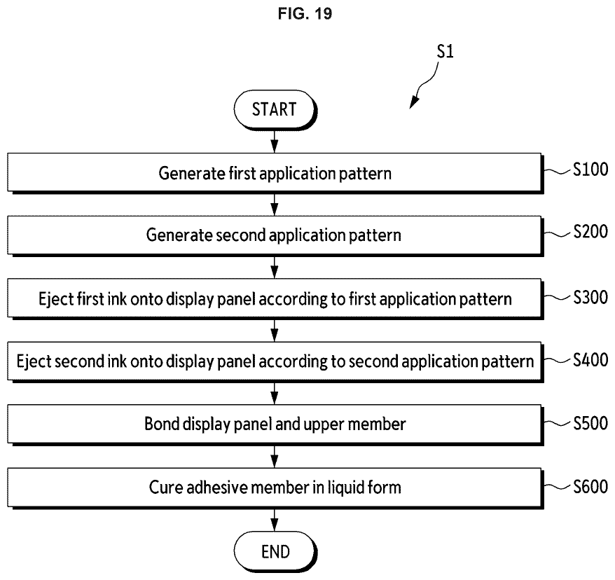

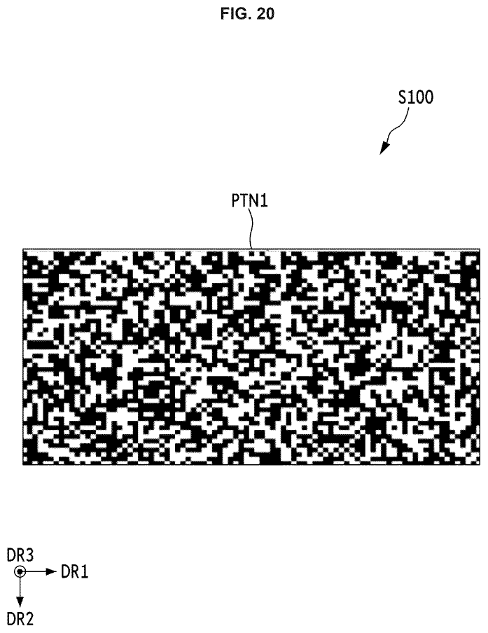

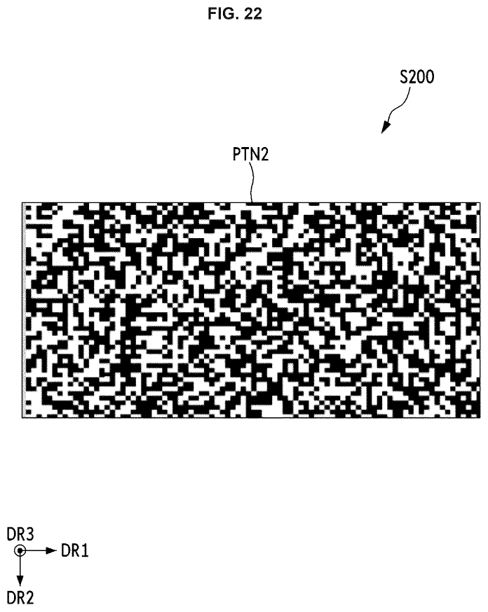

The shape and arrangement of the first resin GLM and the second resin GHM illustrated in FIGS. 14 and 15 are not limited thereto. For example, in FIG. 14, each of the first resin GLM and the second resin GHM is illustrated as having a circular shape, which is only intended to illustrate the approximate positional relationship between the first resin GLM and the second resin GHM, and the actual shapes of the first resin GLM and the second resin GHM are not limited thereto. The same applies to the shapes of the first resin GLM and the second resin GHM in FIG. 15. Furthermore, the positions of the first resin GLM and the second resin GHM included in the mixed portion GM in FIGS. 14 and 15 are merely described as examples, and the positions of the first resin GLM and the second resin GHM may be variously modified according to a first application pattern PTN1 (see FIG. 20) and a second application pattern PTN2 (see FIG. 22) of a manufacturing method S1 (see FIG. 19) of the display device which will be described in more detail later.

An amount of the first resin GLM and an amount of the second resin included in the mixed portion GM may be substantially the same. For example, in one or more embodiments, a density of the mixed portion GM may be about 0.9 to about 1.1 times the average value of a density of the low-rigidity portion GL and a density of the high-rigidity portion GH. For example, the density of the low-rigidity portion GL may be approximately (about) 1 g/cm³ to about 1.1 g/cm³, the density of the high-rigidity portion GH may be approximately (about) 1.15 g/cm³ to about 1.25 g/cm³, and the density of the mixed portion GM may be approximately (about) 1.075 g/cm³ to about 1.175 g/cm³. In one or more embodiments, the density of the low-rigidity portion GL may be approximately (about) 80% to 95% of the density of the high-rigidity portion GH.

Here, the density of the mixed portion GM refers to the average value of the densities measured at random points in the mixed portion GM, the density of the low-rigidity portion GL refers to the average value of the densities measured at random points in the low-rigidity portion GL, and the density of the high-rigidity portion GH refers to the average value of the densities measured at random points in the high-rigidity portion GH.

In one or more embodiments, a difference between a maximum density and a minimum density of the mixed portion GM may be within about 0.2 times the average value of the densities of the mixed portion GM. For example, the density uniformity of the mixed portion GM may be within a range of approximately ±10% of the density of the mixed portion GM.

The display device 10 according to the present embodiment may further improve the thickness uniformity of the adhesive member ADH by uniformly (e.g., substantially uniformly) disposing the first resin GLM and the second resin GHM included in the mixed portion GM.

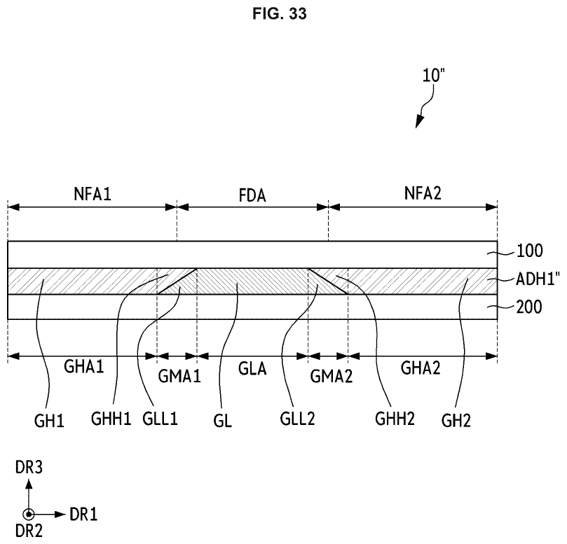

For example, in the mixed portion GM according to the present embodiment, the thickness uniformity of the adhesive member ADH may be further improved compared to an embodiment in which the first resin GLM and the second resin GHM are arranged in a gradual pattern as illustrated in FIG. 33 described later. This will be described in more detail later with reference to FIGS. 33 and 34.

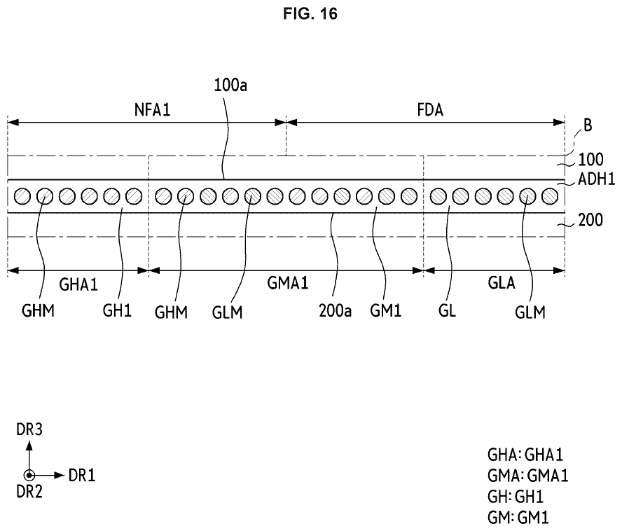

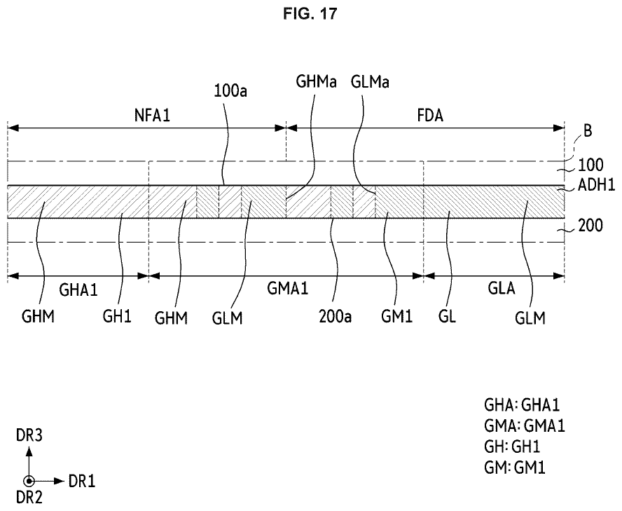

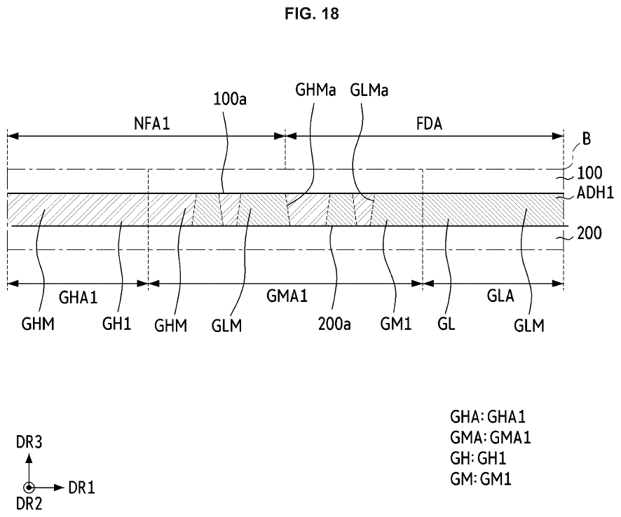

FIG. 16 is a schematic diagram illustrating an enlarged cross-section of area B of FIG. 11 according to one or more embodiments of the present disclosure. FIG. 17 is a cross-sectional view illustrating an example of an enlarged cross-section of area B of FIG. 11 according to one or more embodiments of the present disclosure. FIG. 18 is a cross-sectional view illustrating another example of an enlarged cross-section of area B of FIG. 11 according to one or more embodiments of the present disclosure.

Referring to FIGS. 16 to 18 in addition to FIGS. 8 to 15, each of a bottom surface 100a of the upper protective member 100 and a top surface 200a of the window member 200 in the low-rigidity area GLA may be in direct contact with the first resin GLM. For example, each of the bottom surface 100a of the upper protective member 100 and the top surface 200a of the window member 200 may be in direct contact with the first resin GLM of the low-rigidity portion GL.

In the high-rigidity area GHA, each of the bottom surface 100a of the upper protective member 100 and the top surface 200a of the window member 200 may be in direct contact with the second resin GHM. For example, each of the bottom surface 100a of the upper protective member 100 and the top surface 200a of the window member 200 may be in direct contact with the second resin GHM of the first high-rigidity portion GH1.

In the mixed area GMA, each of the bottom surface 100a of the upper protective member 100 and the top surface 200a of the window member 200 may be in direct contact with the first resin GLM and the second resin GHM. For example, each of the bottom surface 100a of the upper protective member 100 and the top surface 200a of the window member 200 may be in direct contact with the first resin GLM and the second resin GHM of the first mixed portion GM1.

In one or more embodiments, the first resin GLM and the second resin GHM in the mixed area GMA may not overlap in the third direction DR3. As will be described in more detail later in the manufacturing method S1 (see FIG. 19) of the display device, the second resin GHM may be applied to a portion (e.g., a region) in which the first resin GLM is not applied.

In one or more embodiments, as illustrated in FIG. 17, a side surface GLMa of the first resin GLM and a side surface GHMa of the second resin GHM in the mixed area GMA may each be a vertical surface. In one or more embodiments, as illustrated in FIG. 18, the side surface GLMa of the first resin GLM and the side surface GHMa of the second resin GHM in the mixed area GMA may each be an inclined surface. For example, in one or more embodiments, the first resin GLM may have a shape that widens from the top to the bottom in a cross-section view, and the second resin GHM may have a shape that narrows from the top to the bottom in a cross-section view. In one or more embodiments, the first resin GLM may have a shape that narrows from the top to the bottom in a cross-section view, and the second resin GHM may have a shape that widens from the top to the bottom in a cross-section view.

If (e.g., when) the first resin GLM is applied before the second resin GHM, it may have a shape as illustrated in FIG. 18, and if (e.g., when) the second resin GHM is applied before the first resin GLM, it may have an opposite shape (e.g., a shape opposite/reversed to the shape illustrated in FIG. 18.

Hereinafter, a method for manufacturing a display device according to one or more embodiments of the present disclosure will be described.

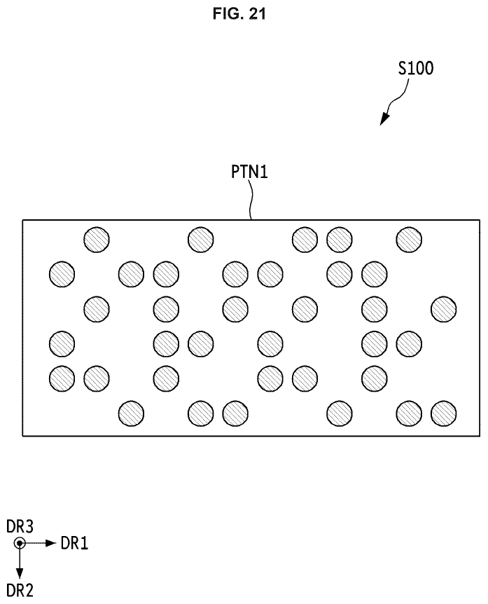

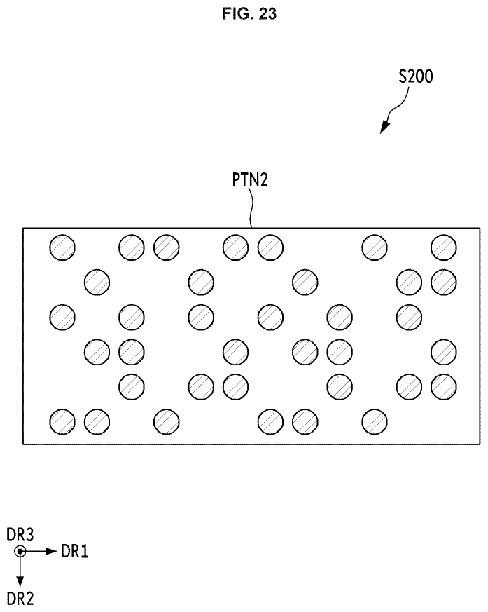

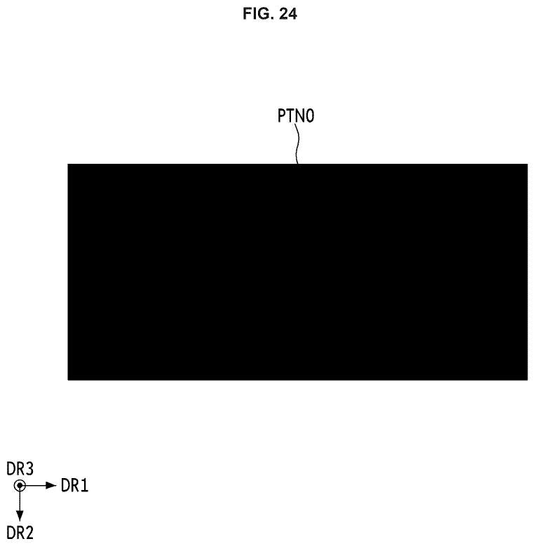

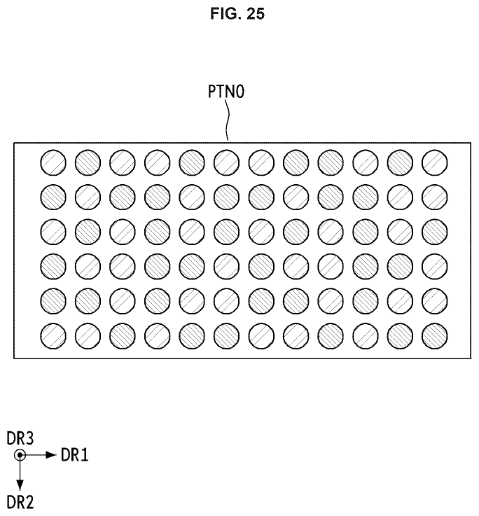

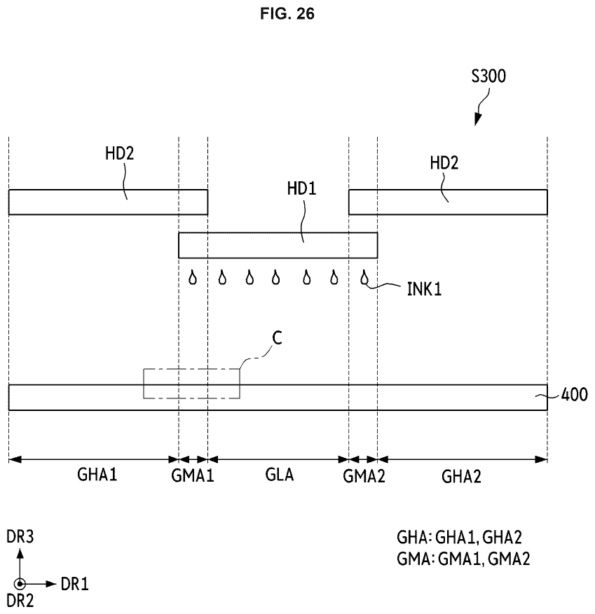

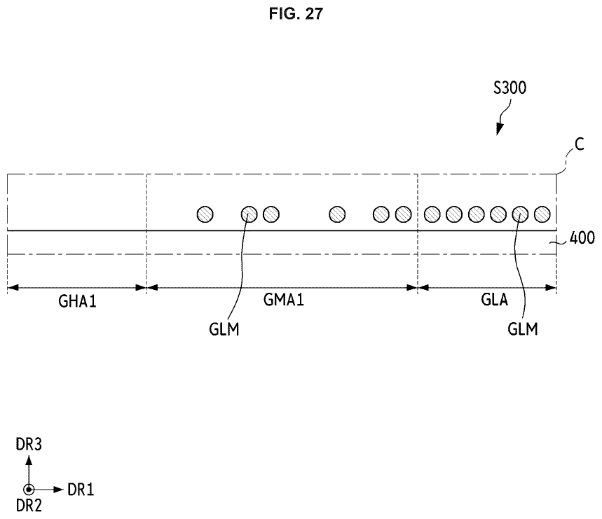

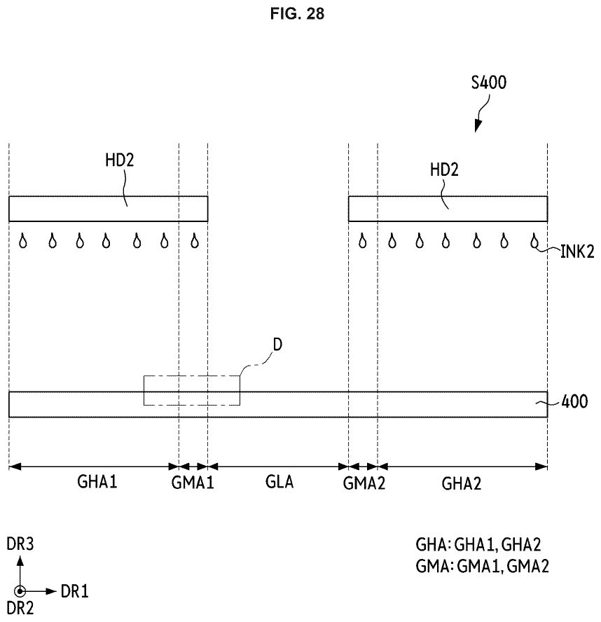

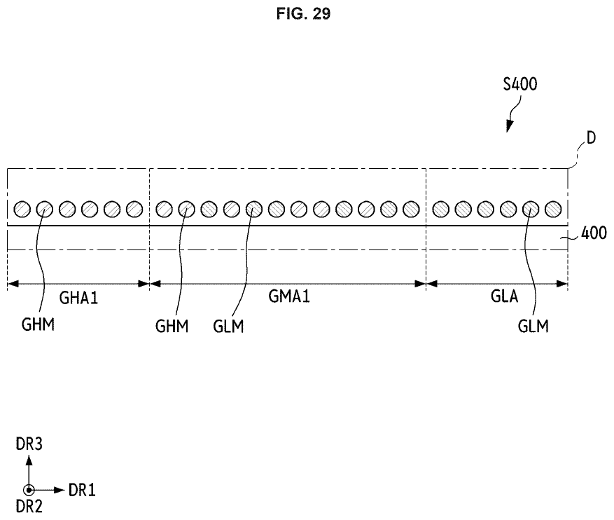

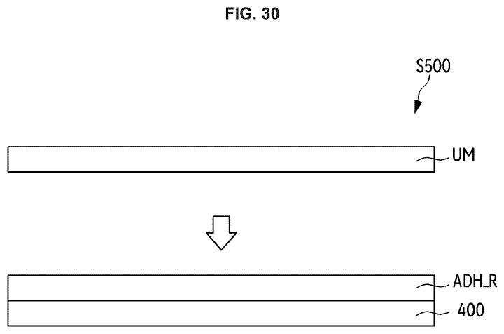

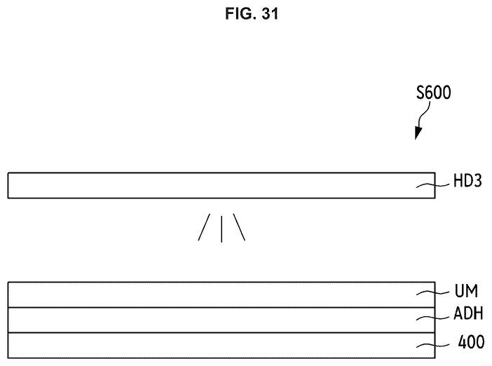

FIG. 19 is a flowchart showing a method for manufacturing a display device according to one or more embodiments. FIG. 20 is a bitmap image illustrating a first application pattern of step (e.g., act or task) S100 of FIG. 19. FIG. 21 is a schematic diagram illustrating the first application pattern of the step (e.g., act or task) S100 of FIG. 19. FIG. 22 is a bitmap image illustrating a second application pattern of step (e.g., act or task) S200 of FIG. 19. FIG. 23 is a schematic diagram illustrating the second application pattern of the step (e.g., act or task) S200 of FIG. 19. FIG. 24 is a bitmap image illustrating a reference pattern in which the first application pattern and the second application pattern are combined. FIG. 25 is a schematic diagram illustrating the reference pattern in which the first application pattern and the second application pattern are combined. FIG. 26 is a cross-sectional view showing step (e.g., act or task) S300 of FIG. 19. FIG. 27 is an enlarged cross-sectional view of area C of FIG. 26. FIG. 28 is a cross-sectional view showing step (e.g., act or task) S400 of FIG. 19. FIG. 29 is a cross-sectional view of area D of FIG. 28. FIGS. 30 and 31 are cross-sectional views showing step (e.g., act or task) S500 of FIG. 19.

Referring to FIGS. 19 to 31, the manufacturing method S1 of the display device according to one or more embodiments may include generating a first application pattern ((e.g., act or task) step S100), generating a second application pattern (step (e.g., act or task) S200), ejecting first ink onto a display panel according to the first application pattern (step (e.g., act or task) S300), ejecting second ink onto the display panel according to the second application pattern (step (e.g., act or task) S400), bonding the display panel and an upper member (step (e.g., act or task) S500), and curing an adhesive member in a liquid form (step (e.g., act or task) S600).

The manufacturing method S1 of the display device according to one or more embodiments may be performed using a manufacturing apparatus of the display device. The manufacturing apparatus of the display device may be an apparatus for applying and curing an adhesive material. The manufacturing apparatus of the display device may include a computation unit that generates an application pattern, an ejection head that ejects ink, and a curing head that cures a liquid adhesive member.

For example, in one or more embodiments, the manufacturing apparatus of the display device may include a computation unit that generates a bitmap, such as a first application pattern PTN1 and a second application pattern PTN2 illustrated in FIG. and FIG. 22, respectively. The manufacturing apparatus of the display device may include a first head HD1 and a second head HD2 as illustrated in FIG. 26 and FIG. 28. The first head HD1 may eject first ink INK1 illustrated in FIG. 26, and the second head HD2 may eject second ink INK2 illustrated in FIG. 28. The manufacturing apparatus of the display device may further include a third head HD3 as illustrated in FIG. 31. The third head HD3 may generate a curing medium such as electromagnetic waves, heat, and air current that may cure an adhesive member ADH_R in a liquid form.

As illustrated in FIG. 20 and FIG. 21, in the step (e.g., act or task) S100 of generating the first application pattern, the computation unit of the manufacturing apparatus of the display device may generate the first application pattern PTN1. The first application pattern PTN1 may be a bitmap indicating a landing point at which the first head HD1 of FIG. 26 ejects the first ink INK1.

For example, in the first application pattern PTN1 of FIG. 20, a black portion (e.g., a portion at which a bit is indicated) may be a landing point of the first ink INK1, and a white portion (e.g., a portion at which a bit is not indicated) may be a point at which the first ink INK1 is not landed (e.g., a non-landing point). In one or more embodiments, a proportion of the landing points and a proportion of the non-landing points in the first application pattern PTN1 may be each 50% and equal to each other.

In one or more embodiments, the first application pattern PTN1 may be a random pattern. The random pattern is a pattern in which the positions of the landing points (e.g., black portions) and the non-landing points (e.g., white portions) are randomly specified.

As illustrated in FIG. 22 and FIG. 23, in the step S200 (e.g., act or task) of generating the second application pattern, the computation unit of the manufacturing apparatus of the display device may generate the second application pattern PTN2. The second application pattern PTN2 may be a bitmap indicating a landing point at which the second head HD2 of FIG. 26 ejects the second ink INK2.

For example, in the second application pattern PTN2 of FIG. 22, a black portion (e.g., a portion at which a bit is indicated) may be a landing point of the second ink INK2, and a white portion (e.g., a portion at which a bit is not indicated) may be a point at which the second ink INK2 is not landed (e.g., a non-landing point). In one or more embodiments, a proportion of the landing points and a proportion of the non-landing points in the second application pattern PTN2 may be each 50% and equal to each other.

The second application pattern PTN2 may be an inverse pattern of the first application pattern PTN1. The inverse pattern refers to a pattern in which the positions of the landing point (e.g., black portion) and the non-landing point (e.g., white portion) are opposite to those of the first application pattern PTN1.

As illustrated in FIGS. 24 and 25, the computation unit of the manufacturing apparatus of the display device may store information related to a reference pattern PTN0. The reference pattern PTN0 is a pattern that represents the plane of the mixed area GMA or the mixed portion GM described above with reference to FIG. 8 and/or the like, as a bitmap. For example, the reference pattern PTN0 is a pattern that represents all points on which the first ink INK1 and the second ink INK2 may land on the plane of the mixed area GMA or the mixed portion GM, as a bitmap.

First, the computation unit of the manufacturing apparatus of the display device may generate the first application pattern PTN1 according to a method such as a random number generating method or a noise generating method. The first application pattern PTN1 may be newly generated each time the first head HD1 ejects the first ink INK1. Accordingly, the landing point of the first ink INK1 may be randomly formed for each ejection of the first ink INK1.

Next, the computation unit of the manufacturing apparatus of the display device may generate the second application pattern PTN2 that is opposite to the first application pattern PTN1 by comparing the reference pattern PTN0 with the first application pattern PTN1. For example, the landing point (e.g., black portion) of the first application pattern PTN1 becomes the non-landing point (e.g., white portion) of the second application pattern PTN2, and the non-landing point (e.g., white portion) of the first application pattern PTN1 becomes the landing point (e.g., black portion) of the second application pattern PTN2.

For example, in one or more embodiments, the reference pattern PTN0 illustrated in FIG. 24 may be substantially identical to the combination of the first application pattern PTN1 illustrated in FIG. 20 and the second application pattern PTN2 illustrated in FIG. 22. in one or more embodiments, the reference pattern PTN0 illustrated in FIG. 25 may be substantially identical to the combination of the first application pattern PTN1 illustrated in FIG. 21 and the second application pattern PTN2 illustrated in FIG. 23.

As illustrated in FIGS. 26 and 27, in the step (e.g., act or task) S300 of ejecting the first ink onto the display panel according to the first application pattern, in one or more embodiments, the first head HD1 may eject the first ink INK1 onto the display panel 400. The first ink INK1 may be the first resin GLM in a liquid form. The first ink INK1 may include an OCR.

Hereinafter, embodiments in which the first ink INK1 and the second ink INK2 are ejected onto the display panel 400 will be mainly described, but embodiments of the present disclosure are not limited thereto. For example, the same technical idea may also be applied to embodiments in which the first ink INK1 and the second ink INK2 are ejected onto the optical member 300 or onto the window member 200 described with reference to FIG. 5.

The first head HD1 may eject the first ink INK1 to an entire surface of the low-rigidity area GLA. The first head HD1 may eject the first ink INK1 to the mixed area GMA according to the first ejection pattern PTN1.

Accordingly, as illustrated in FIG. 27, the first resin GLM in a liquid form may be applied to a portion of the mixed area GMA, and the first resin GLM may not be applied to another (e.g., the rest) portion of the mixed area GMA. In the mixed area GMA, the area of the portion to which the first resin GLM is applied and the area of the portion to which the first resin GLM is not applied may be substantially the same.

As illustrated in FIGS. 28 and 29, in the step (e.g., act or task) S400 of ejecting the second ink onto the display panel according to the second application pattern, the second head HD2 may eject the second ink INK2 onto the display panel 400. The second ink INK2 may be the second resin GHM in a liquid form. The second ink INK2 may include an OCR.

The second head HD2 may eject the second ink INK2 to an entire surface of the high-rigidity area GHA. The second head HD2 may eject the second ink INK2 according to the second ejection pattern PTN2 to the mixed area GMA. The second ink INK2 may be ejected into a portion to which the first ink INK1 is not ejected.

Accordingly, as illustrated in FIG. 29, the second resin GHM in a liquid form may be applied to a portion of the mixed area GMA, and the second resin GHM may not be applied to the portion of the mixing area GLA that the first resin GLM has been applied to. In the mixed area GMA, the area of the portion to which the second resin GHM is applied and the area of the portion to which the second resin GHM is not applied may be substantially the same. The second resin GHM may be applied to a portion to which the first resin GLM is not applied. In other words, in the mixed area GMA, the first resin GLM may have the first ejection pattern PTN1, and the second resin GHM may have the second ejection pattern PTN2. For example, in the mixed area GMA, the first resin GLM may follow the first ejection pattern PTN1, and the second resin GHM may follow the second ejection pattern PTN2.

In one or more embodiments, the modulus of the first ink INK1 may be less than the modulus of the second ink INK2. The modulus of the first ink INK1 may be approximately (about) 1 MPa or less at 25° C., and the modulus of the second ink INK2 may be approximately (about) 10 MPa or more at 25° C.

As illustrated in FIG. 30, in the step (e.g., act or task) S500 of bonding the display panel and the upper member, the first ink INK1 and the second ink INK2 may be applied to form the adhesive member ADH_R in a liquid form on the display panel 400. An upper member UM (e.g., the upper protective member 100 or the window member 200 of FIG. 5) may be bonded onto the adhesive member ADH_R in a liquid form.

In one or more embodiments, a preliminary curing process may be performed prior to bonding of the upper member UM to prevent or reduce the adhesive member ADH_R in a liquid form from overflowing during the bonding process and to increase the tackiness (or adhesion) of the adhesive member ADH_R in a liquid form.

The preliminary curing process is a process of curing the adhesive member ADH_R in a liquid form to a lesser degree than a main curing process of the step (e.g., act or task) S600 described in more detail later. A hardness of the adhesive member after preliminary curing may be less than a hardness of the adhesive member after main curing. The preliminary curing process may be carried out by natural curing, heat curing, ultraviolet curing, and/or the like

As illustrated in FIG. 31, in the step (e.g., act or task) S600 of curing the adhesive member in a liquid form, the third head HD3 may apply a curing medium to the adhesive member ADH_R in a liquid form to which the upper member UM is bonded. The curing medium may include electromagnetic waves, heat, air current (wind), and/or the like. The adhesive member ADH_R in a liquid form may be cured into the adhesive member ADH in a solid form by a curing medium. In one or more embodiments, if (e.g., when) the preliminary curing process is included as described above, the curing process of the step (e.g., act or task) S600 may be the main curing process.

Hereinafter, thickness profiles of the respective adhesive members of display devices according to comparative examples and the display device according to one or more embodiments are compared and described.

FIG. 32 is a cross-sectional view showing a part of a display device according to a first comparative example of the present disclosure. FIG. 33 is a cross-sectional view showing a part of a display device according to a second comparative example of the present disclosure. FIG. 34 is a graph illustrating the thickness profiles of the respective adhesive members of the display devices according to the first comparative example, the second comparative example, and one example embodiment of the present disclosure, e.g., the vertical axis indicates thicknesses of the respective adhesive members of the display devices according to the first comparative example, the second comparative example, and the example embodiment of the present disclosure, and the horizontal axis indicates widths of the respective adhesive members of the display devices according to the first comparative example, the second comparative example, the example embodiment.

Referring to FIGS. 32 to 34 in addition to FIG. 11, an adhesive member ADH′ of a display device 10′ according to the first comparative embodiment may not include (e.g., may exclude) the mixed area GMA and the mixed portion GM. Accordingly, the low-rigidity area GLA may be in direct contact with the first high-rigidity area GHA1 and the second high-rigidity area GHA2. Additionally, the low-rigidity portion GL may be in direct contact with the first high-rigidity portion GH1 and the second high-rigidity portion GH2.

An adhesive member ADH″ of a display device 10″ according to the second comparative example may not include (e.g., may exclude) the first mixed portion GM1 and the second mixed portion GM2.

The adhesive member ADH″ of the display device 10″ according to the second comparative embodiment may include a first sub-low-rigidity portion GLL1 arranged on one side of the low-rigidity portion GL in the first direction DR1 and a second sub-low-rigidity portion GLL2 arranged on the other side of the low-rigidity portion GL in the first direction DR1. The first sub-low-rigidity portion GLL1 and the second sub-low-rigidity portion GLL2 may be constituents to be included in the low-rigidity portion GL.

In addition, the adhesive member ADH″ of the display device 10″ according to the second comparative example may include a first sub-high-rigidity portion GHH1 arranged on one side of the first high-rigidity portion GH1 in the first direction DR1 and a second sub-high-rigidity portion GHH2 arranged on the other side of the second high-rigidity portion GH2 in the first direction DR1. The first sub-high-rigidity portion GHH1 may be a constituent included in the first high-rigidity portion GH1, and the second sub-high-rigidity portion GHH2 may be a constituent included in the second high-rigidity portion GH2.

As with the display device 10′ according to the first comparative embodiment, in the display device 10″ according to the second comparative embodiment, the low-rigidity portion GL may be in direct contact with the first high-rigidity portion GH1 and the second high-rigidity portion GH2. The adhesive member ADH″ of the display device 10″ according to the second comparative embodiment may include an interface between the low-rigidity portion GL and the first high-rigidity portion GH1 and an interface between the low-rigidity portion GL and the second high-rigidity portion GH2 in the mixed area GMA. The interface between the low-rigidity portion GL and the first high-rigidity portion GH1 and the interface between the low-rigidity portion GL and the second high-rigidity portion GH2 may each be an inclined surface. For example, the display device 10″ according to the second comparative embodiment may include a gradual pattern in the mixed area GMA.

In the graphs illustrated in FIG. 34, a first graph G1 is a graph illustrating a thickness profile of the adhesive member ADH′ of the display device 10′ according to the first comparative embodiment which is taken along the first direction DR1, a second graph G2 is a graph illustrating a thickness profile of the adhesive member ADH″ of the display device 10″ according to the second comparative embodiment which is taken along the first direction DR1, and the third graph G3 is a graph illustrating a thickness profile of the adhesive member ADH of the display device 10 according to one embodiment of the present disclosure which is taken along the first direction DR1.

In the case of the display device 10′ according to the first comparative example, a thickness deviation has greatly occurred near the interface between the low-rigidity portion GL and the first high-rigidity portion GH1 and the interface between the low-rigidity portion GL and the second high-rigidity portion GH2. Even in the case of the display device 10″ according to the second comparative example, a thickness deviation has greatly occurred near the interface (e.g., the first mixed area GMA1) between the low-rigidity portion GL and the first high-rigidity portion GH1 and the interface (e.g., the second mixed area GMA2) between the low-rigidity portion GL and the second high-rigidity portion GH2. In contrast, in the case of the display device 10 according to one embodiment of the present disclosure, almost no thickness deviation has occurred in both (e.g., simultaneously) the first mixed area GMA1 and the second mixed area GMA2.

For example, a difference G1_H between the maximum value and the minimum value of the first graph G1 is approximately (about) 25.4 μm, a difference G2_H between the maximum value and the minimum value of the second graph G2 is approximately (about) 15.7 μm, and a difference G3_H between the maximum value and the minimum value of the third graph G3 is approximately (about) 4.2 μm.

Such a thickness deviation may be due to a difference in the curing characteristics of the first resin GLM included in the low-rigidity portion GL and the curing characteristics of the second resin GHM included in the high-rigidity portion GH. The curing characteristics of a resin refer to characteristics such as curing rate, expansion rate before and after curing, and hardness after curing, of the resin.

In this way, the adhesive member ADH of the display device 10 according to one or more embodiments of the present disclosure may prevent the low-rigidity portion GL and the high-rigidity portion GH from being in direct contact with each other in the mixed area GMA and the mixed portion GM, and may improve the thickness uniformity of the adhesive member ADH by evenly applying the first resin GLM and the second resin GHM in the mixed area GMA and the mixed portion GM such that the low-rigidity portion GL and the high-rigidity portion GH do not form boundary surfaces such as inclined surfaces. For example, the adhesive member ADH′ of the display device 10′ according to the first comparative embodiment may exclude the mixed area GMA and the mixed portion GM, resulting in the low-rigidity area GLA being in direct contact with the first and second high-rigidity areas GHA1 and GHA2. Similarly, the adhesive member ADH″ of the display device 10″ according to the second comparative example may exclude the first and second mixed portions GM1 and GM2, but include sub-low-rigidity portions GLL1 and GLL2 on either side of the low-rigidity portion GL, and sub-high-rigidity portions GHH1 and GHH2 on either side of the high-rigidity portions GH1 and GH2. In both comparative embodiments, the low-rigidity portion GL is in direct contact with the high-rigidity portions GH1 and GH2, leading to significant thickness deviations at their interfaces. In contrast, the adhesive member ADH of the display device 10 according to embodiments of the present disclosure shows minimal thickness deviation in the mixed areas GMA1 and GMA2, for example, with a thickness deviation of about 4.2 μm only (see the third graph). This improvement is attributed to the even application and curing characteristics of the first resin GLM and the second resin GHM in the mixed areas GMA1 and GMA2, preventing direct contact between the low-rigidity and high-rigidity portions and enhancing thickness uniformity.

In the present disclosure, it will be understood that the terms “comprise(s)/comprising,” “include(s)/including,” or “have/has/having” specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light emitting element, the display panel, the display device, the electronic device/apparatus, the device-manufacturing apparatus (e.g., adhesive member-manufacturing apparatus), or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In concluding the detailed description, those skilled in the art will appreciate that many variations and modifications can be made to the example embodiments without substantially departing from the principles of the present disclosure. Therefore, the disclosed embodiments of present disclosure are used in a generic and descriptive sense only and not for purposes of limitation. It is further to be understood that the scope of the present disclosure are defined by the appended claims and equivalents thereof rather than the detailed description described above, and all modifications and alterations derived from the claims and their equivalents fall within the scope of the present disclosure.

What is claimed is:

1. A display device comprising:
a display panel;
an upper member on the display panel; and
an adhesive member between the display panel and the upper member, the adhesive member comprising:
a first portion containing a first resin;
a second portion containing a second resin having a higher modulus than the first resin and on at least one side of the first portion; and
a third portion containing the first resin and the second resin and between the first portion and the second portion,
wherein, in the third portion, each of the first resin and the second resin is in direct contact with a bottom surface of the upper member.

2. The display device of claim 1, wherein, in the third portion, each of the first resin and the second resin is in direct contact with a top surface of the display panel.

3. The display device of claim 1, wherein an amount of the first resin in the third portion is equal to an amount of the second resin in the third portion.

4. The display device of claim 1, wherein a density of the third portion is greater than a density of the first portion and less than a density of the second portion, or
the density of the third portion is less than the density of the first portion and greater than the density of the second portion.

5. The display device of claim 4, wherein the density of the third portion is about 0.9 to about 1.1 times an average value of the density of the first portion and the density of the second portion.

6. The display device of claim 5, wherein the density of the third portion is equal to the average value of the density of the first portion and the density of the second portion.

7. The display device of claim 4, wherein a difference between a maximum density and a minimum density of the third portion is within about 0.2 times an average value of densities of the third portion.

8. The display device of claim 1, wherein a thickness deviation of the third portion is within about 5 μm.

9. The display device of claim 1, wherein, in the third portion, the first resin and the second resin do not overlap each other in a thickness direction of the adhesive member.

10. The display device of claim 1, wherein, in the third portion, a boundary between a side surface of the first resin and a side surface of the second resin is an inclined surface.

11. The display device of claim 1, wherein the display panel comprises a folding area, and a non-folding area on one side of the folding area, and
the first portion overlaps the folding area, the second portion overlaps the non-folding area, and the third portion is adjacent to a boundary between the folding area and the non-folding area.

12. The display device of claim 1, wherein a modulus of the second portion is greater than a modulus of the first portion, and
wherein a modulus of the third portion is greater than a modulus of the first portion and less than a modulus of the second portion.

13. The display device of claim 1, wherein the first portion and the second portion are not in direct contact with each other.

14. A method, comprising:
generating a first application pattern and a second application pattern;
ejecting first ink according to the first application pattern;
ejecting second ink according to the second application pattern; and
curing the first ink and the second ink,
wherein the second application pattern is an inverse pattern of the first application pattern, and
the method is a method for manufacturing a display device.

15. The method of claim 14, wherein each of the first application pattern and the second application pattern is a bitmap,
a portion of the first application pattern at which a bit is indicated coincides with a portion of the second application pattern at which a bit is not indicated, and
a portion of the first application pattern at which a bit is not indicated coincides with a portion of the second application pattern at which a bit is indicated.

16. The method of claim 15, wherein, in the first application pattern, a proportion of the portion at which the bit of the first application pattern is indicated and a proportion of the portion at which the bit of the first application pattern is not indicated are substantially equal to each other.

17. The method of claim 14, wherein a point where the first ink is ejected and a point where the second ink is ejected do not overlap.

18. The method of claim 14, wherein the first application pattern is a random pattern.

19. The method of claim 14, wherein each of the first ink and the second ink comprises an optical clear resin, and
a modulus of the first ink is less than a modulus of the second ink.

20. An electronic device comprising
a display device,
wherein the display device comprises:
a display panel;
an upper member on the display panel; and
an adhesive member between the display panel and the upper member, the adhesive member comprising:
a first portion containing a first resin;
a second portion containing a second resin having a higher modulus than the first resin and on at least one side of the first portion; and
a third portion containing the first resin and the second resin and between the first portion and the second portion, and
wherein, in the third portion, each of the first resin and the second resin is in direct contact with a bottom surface of the upper member.
